(19) United States
(12) Patent Application Publication
(10) Pub. No.: US 2025/0351548 A1
(43) Pub. Date: Nov. 13, 2025

(54) DIELECTRIC MATERIALS FOR STACKED TRANSISTOR STRUCTURES AND RELATED METHODS

(71) Applicant: Taiwan Semiconductor Manufacturing Company, Ltd., Hsinchu (TW)

(72) Inventors: Cheng-Ming Lin, Kaohsiung City (TW); Jin-Hao Jhang, Chubei City (TW); Wei-Yen Woon, Taoyuan City (TW); Szuya Liao, Zhubei (TW)

(21) Appl. No.: 19/278,294

(22) Filed: Jul. 23, 2025

Related U.S. Application Data
(63) Continuation of application No. 18/646,170, filed on Apr. 25, 2024.
(60) Provisional application No. 63/598,989, filed on Nov. 15, 2023.

(51) Int. Cl. H10D 84/03; H10D 30/01; H10D 30/43; H10D 30/67; H10D 62/10; H10D 64/01; H10D 84/01; H10D 84/85; H10D 88/00

(52) U.S. Cl. CPC H10D 84/038; H10D 30/014; H10D 30/43; H10D 30/6735; H10D 30/6739; H10D 62/121; H10D 64/017; H10D 84/0167; H10D 84/0181; H10D 84/856; H10D 88/01

(57) ABSTRACT

Gate dielectric materials and related methods for stacked device structures such as a complementary field-effect transistor (CFET) are disclosed herein. An exemplary method includes forming a two-dimensional (2D) dielectric material over a semiconductor channel layer. In some embodiments, the method further includes depositing a gate dielectric layer over the 2D dielectric material. In some examples, the method further includes forming a metal gate electrode over the gate dielectric layer. In various embodiments, a dipole is formed substantially within the 2D dielectric material, where the dipole is configured to modulate a threshold voltage (Vt) of the semiconductor device.

### CROSS-REFERENCE TO RELATED APPLICATIONS

This application is a continuation of U.S. patent application Ser. No. 18/646,170, filed Apr. 25, 2024, which claims the benefit of U.S. Provisional Patent Application Ser. No. 63/598,989, filed Nov. 15, 2023, the entire disclosures of which are incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, by reducing minimum IC feature size), thereby improving production efficiency and lowering associated costs. However, such scaling has also increased complexity of IC manufacturing processes. Thus, realizing continued advances in IC devices and their performance requires similar advances in IC manufacturing processes and technology.

As one example, complementary field effect transistors (CFETs), which include a first transistor of a first conductivity type (e.g., n-type or p-type) vertically stacked over a second transistor having an opposite conductivity type, have been introduced in an effort to provide needed density reduction for advanced IC technology nodes. However, fabrication of such stacked device structures introduces another set of challenges. As a result, existing implementations have not been satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a fragmentary cross-sectional view of a stacked device structure, in portion or entirety, according to various aspects of the present disclosure.

FIG. 1B is a fragmentary cross-sectional view of another stacked device structure, in portion or entirety, according to various aspects of the present disclosure.

FIG. 2A is a flow chart of a method, in portion or entirety, for forming a gate structure of a transistor, according to various aspects of the present disclosure.

FIGS. 2B, 2C, 2D, and 2E illustrate embodiments of various gate structures that may be formed in correspondence with the method of FIG. 2A, according to various aspects of the present disclosure.

FIG. 2F illustrates a dipole profile corresponding to the embodiments of the gate structures disclosed herein, according to some aspects of the present disclosure.

FIG. 3 is a flow chart of a method for monolithically fabricating a stacked device structure, such as the stacked device structure of FIG. 1A, that implements the methods of forming a gate structure of FIGS. 2A-2F, according to various aspects of the present disclosure.

FIGS. 4A, 4B, 4C, 4D, 4E, 4F, 4G, and 4H are cross-sectional views of a stacked device structure, in portion or entirety, at various fabrication stages, such as those associated with the methods of FIG. 3 and FIGS. 2A-2F, according to various aspects of the present disclosure.

FIG. 5 is a flow chart of a method for sequentially fabricating a stacked device structure, such as the stacked device structure of FIG. 1B, that implements the methods of forming a gate structure of FIGS. 2A-2F, according to various aspects of the present disclosure.

FIGS. 6A, 6B, 6C, 6D, 6E, 6F, and 6G are cross-sectional views of a stacked device structure, in portion or entirety, at various fabrication stages, such as those associated with the methods of FIG. 5 and FIGS. 2A-2F, according to various aspects of the present disclosure.

### DETAILED DESCRIPTION

The present disclosure relates generally to gate dielectric materials for stacked device structures, such as a transistor stack having an n-type field effect transistor (NFET) and a p-type field effect transistor (PFET). More particularly, embodiments of the present disclosure relate to a two-dimensional (2D) gate dielectric material (e.g., such as a 2D silica and/or 2D silicate) that provides for both threshold voltage (Vt) tuning and equivalent oxide thickness (EOT) scaling in stacked device structures.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion in the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” may encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Stacked transistor structures can provide needed density reduction for advanced integrated circuit (IC) technology nodes. A stacked transistor structure vertically stacks a first transistor (i.e., an upper/top transistor) over a second transistor (i.e., a lower/bottom transistor). The stacked transistor structure provides a complementary field effect transistor (CFET) when the first transistor and the second transistor have opposite conductivity types (i.e., an n-type transistor and a p-type transistor). The first transistor and the second transistor are separated by an insulation layer, which is typically formed by replacing a sacrificial layer of a semiconductor layer stack with a dielectric layer during processing of the semiconductor layer stack to form the first transistor and the second transistor. For example, a semiconductor layer stack may include a sacrificial layer between a first set of semiconductor layers and a second set of semiconductor layers, where the first set of semiconductor layers is processed to form the first transistor and the second set of semiconductor layers is processed to form the second transistor. After partially processing the semiconductor layer stack, forming the insulation layer may include removing the sacrificial layer to form a gap between the first set of semiconductor layers and the second set of semiconductor layers, and filling the gap with an insulation material, such as a dielectric material.

As an alternative to bonding techniques that utilize such a gap fill step, some techniques for stacked transistor structures utilize plasma activated wafer bonding to provide an insulation layer between a first transistor and a second transistor. In an exemplary plasma activated wafer bonding process, a first bonding dielectric layer may be formed on a first substrate and a second bonding dielectric layer may be formed on a second substrate. Thereafter, a plasma activation process may be performed to each of the first and second bonding dielectric layers on each of the first and second substrates, respectively, to form plasma activated surfaces thereon. The plasma activated surfaces on each of the first and second bonding dielectric layers on the first and second substrates may then be bonded by bringing the respective plasma activated surfaces into contact with each other. Such techniques eliminate the need to replace a sacrificial layer with a dielectric layer, which may eliminate seam formation in the insulation layer and reduce damage to the insulation layer and/or other device features that may occur via seams during processes that utilize gap filling.

In various embodiments, the types of transistors used to provide the first and/or second transistor of a stacked transistor structure may include planar transistors, fin field-effect transistors (FinFETs), and/or gate-all-around (GAA) transistors including nanosheet transistors and nanowire transistors. Regardless of the particular type of transistor used, a gate structure of the transistor may include a high-K/metal gate structure. In some implementations, the high-K/metal gate structure may include an interfacial layer (IL) formed over a semiconductor channel layer (e.g., such as a Si-, SiGe-, or Ge-based material layer), a high-K dielectric layer (e.g., such as a Hf-based dielectric layer, a Zr-based dielectric layer, or other high-K dielectric layer) formed over the IL, and a metal gate electrode formed over the high-K dielectric layer. High-K gate dielectrics, as used and described herein, include dielectric materials having a high dielectric constant, for example, greater than that of thermal silicon oxide (˜3.9). In some cases, the metal gate electrode may include a metal layer such as Ti, Al, W, Ta, a metal compound such as TaN, TiN, TiAl, WN, or other metal-containing material layer.

In various examples, the IL includes a silicon-containing dielectric material such as amorphous SiOx (a-SiOx). As noted above, the IL may be disposed between the semiconductor channel layer and the high-K dielectric layer. In at least some existing implementations, a dipole drive-in based method may be used for modulating a transistor threshold voltage (Vt) by tuning a work function (WF) of the transistor. For instance, a dipole inducing layer may be formed over the high-K dielectric layer, and atoms of the dipole inducing layer may be driven into the high-K dielectric layer such that a dipole may be formed at an interface between the high-K dielectric layer and the IL. The dipole formed, in turn, will modulate the transistor WF and Vt and can help to enhance device performance. The dipole drive-in based method, however, is performed using a high-temperature process that is not easy to control and which may instead cause degradation in device performance. In addition to Vt tuning, equivalent oxide thickness (EOT) scaling is desirable for improving device performance. However, the thickness of the IL is difficult to scale down, at least in part, because of the possibility of high gate leakage that may occur as a result of physical thickness scaling of the IL (e.g., scaling down the thickness of the a-SiOx IL). In addition to the above challenges, dangling bonds at the interface between the IL (e.g., the a-SiOx) and the underlying semiconductor channel layer (e.g., such as Si) may result in a high interface trap density, further degrading device performance.

Embodiments of the present disclosure offer advantages over the existing art, though it is understood that other embodiments may offer different advantages, not all advantages are necessarily discussed herein, and no particular advantage is required for all embodiments. For example, embodiments discussed herein include gate dielectric materials and related methods for stacked device structures, such as stacked transistor structures. In some embodiments, a two-dimensional (2D) dielectric material is disposed between the semiconductor channel layer and the high-K dielectric layer of a gate structure, essentially replacing the IL used in some existing applications (e.g., a-SiOx). In various examples, the 2D dielectric material may include 2D silica and/or 2D silicate (e.g., such as c-SiOx, c-MSiOx, where ‘M’ is a metal), which is a layered polymorph of silicon dioxide, and which has hexagonal crystal symmetry. In particular, the 2D dielectric material disclosed herein provides for both Vt tuning and EOT scaling, without compromising device performance. For instance, an interface between the 2D dielectric material and the underlying semiconductor channel layer (e.g., such as Si) is substantially flat, promoting improved device performance. The crystalline structure of the 2D dielectric material, for example as opposed to the amorphous SiOx used in some existing implementations, also provides for enhanced device reliability. In various embodiments, the ultrathin thickness of the 2D dielectric material provides for a scalable EOT, further enhancing device performance. In addition, and in some embodiments, the 2D dielectric material may be directly doped during the deposition process, thereby providing for the formation of a dipole (e.g., for WF and Vt tuning) in a controllable manner. Additional details of embodiments of the present disclosure are provided below, and additional benefits and/or other advantages will become apparent to those skilled in the art having benefit of the present disclosure.

As previously noted, the types of transistors used to provide the first and/or second transistor of a stacked transistor structure may include planar transistors, FinFETs, and/or GAA transistors including nanosheet transistors and nanowire transistors. While not limited thereto, for purposes of the discussion that follows, various embodiments will be discussed as using GAA transistors to provide the first and second transistors of a stacked transistor structure. The disclosed stacked transistor structures may also provide a CFET, where the first transistor and the second transistor have opposite conductivity types (e.g., an n-type transistor and a p-type transistor). The GAA transistors used to implement the CFET, as described in more detail below and in some examples, include a gate structure having a high-K/metal gate structure. The high-K/metal gate structure, in various embodiments, includes a 2D dielectric material (e.g., 2D silica and/or 2D silicate) formed over a semiconductor channel layer (e.g., such as a Si-, SiGe-, or Ge-based material layer), a high-K dielectric layer (e.g., such as a Hf-based dielectric layer, a Zr-based dielectric layer, or other high-K dielectric layer) formed over the 2D dielectric material, and a metal gate electrode formed over the high-K dielectric layer.

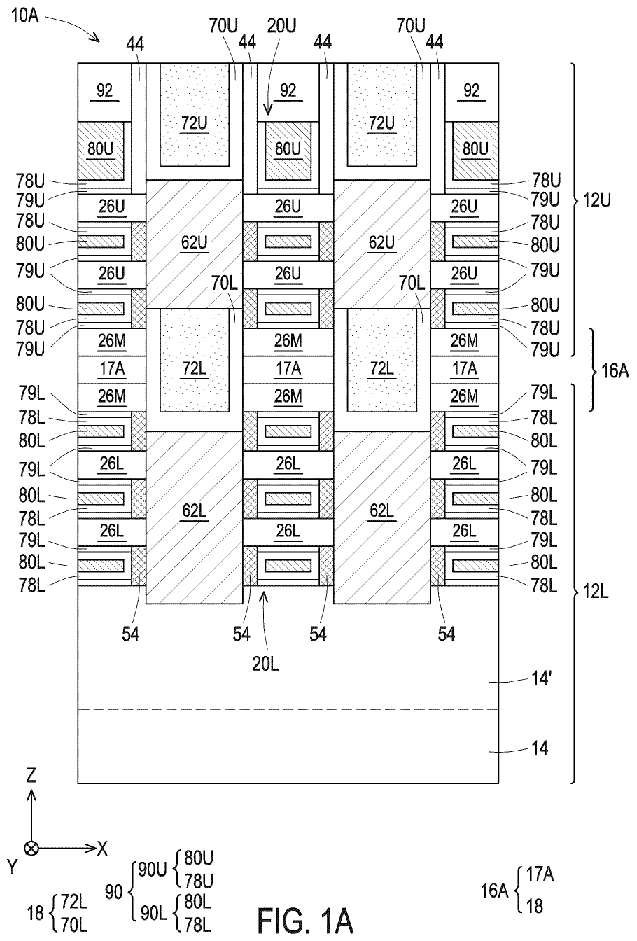

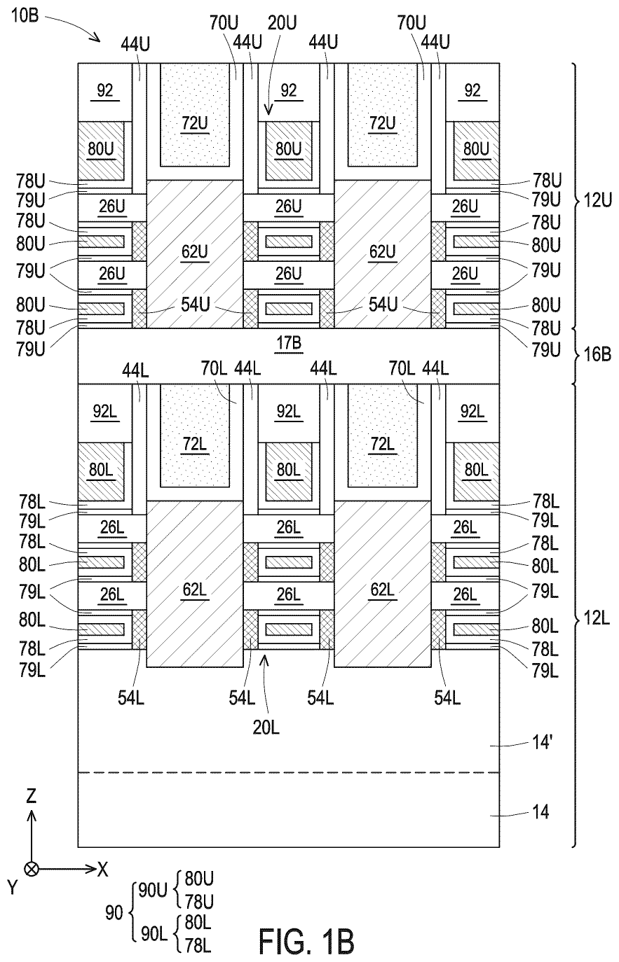

Referring now to the figures, FIG. 1A provides a fragmentary cross-sectional view of a stacked device structure 10A, in portion or entirety, according to various aspects of the present disclosure. Stacked device structure 10A is fabricated monolithically, and thus may be referred to as a monolithic stacked device structure. Stacked device structure 10A includes a device stack having an upper device 12U vertically stacked over a lower device 12L, a substrate 14, and an isolation structure 16A between and separating the upper device 12U and the lower device 12L. Isolation structure 16A includes isolation structures 17A and isolation structures 18. In some embodiments, the upper device 12U and the lower device 12L are stacked back-to-front. For example, as described further below, isolation structure 16A may bond and/or attach a backside of the upper device 12U to a frontside of the lower device 12L, and isolation structure 16A may be referred to as a bonding layer/structure. FIG. 1A has been simplified for the sake of clarity to better understand the inventive concepts of the present disclosure. Additional features may be added to the stacked device structure 10A, and some of the features described below may be replaced, modified, or eliminated in other embodiments of the stacked device structure 10A.

In FIG. 1A, the upper device 12U and the lower device 12L each include at least one electrically functional device, such as an upper transistor 20U and a lower transistor 20L, respectively. Stacked device structure 10A thus includes a transistor stack having a top transistor (e.g., transistor 20U) and a bottom transistor (e.g., transistor 20L) separated and/or electrically isolated from one another by isolation structure 16A. In some embodiments, the lower transistor 20L and the upper transistor 20U are transistors of an opposite conductivity type. For example, transistor 20L is a p-type transistor, and transistor 20U is an n-type transistor, or vice versa. In such embodiments, the lower transistor 20L and the upper transistor 20U form a CFET. In some embodiments, the lower transistor 20L and the upper transistor 20U are transistors of a same conductivity type. For example, transistor 20L and transistor 20U are both n-type transistors or both p-type transistors.

Device 12U includes various features and/or components, such as semiconductor layers 26U, semiconductor layers 26M, gate spacers 44, inner spacers 54, epitaxial source/drains 62U, a contact etch stop layer (CESL) 70U, an interlayer dielectric (ILD) layer 72U, gate dielectrics 78U and gate electrodes 80U (which collectively form gate stacks 90U), and hard masks 92. Device 12L also includes various features and/or components, such as mesas 14′ (e.g., extensions of substrate 14), semiconductor layers 26L, semiconductor layers 26M, substrate isolation structures, inner spacers 54, epitaxial source/drains 62L, a CESL 70L, an ILD layer 72L, and gate dielectrics 78L and gate electrodes 80L (which collectively form gate stacks 90L). A respective gate stack 90U and a respective gate stack 90L are collectively referred to as a gate 90 of stacked device structure 10A, which may be a metal gate or a high-k/metal gate of a respective CFET. Gate stacks 90U are separated from gate stacks 90L by isolation structures 17A and semiconductor layers 26M, and epitaxial source/drains 62U are separated from epitaxial source/drains 62L by isolation structures 18. In stacked device structure 10B, discussed below, isolation structures 17B may provide electrical isolation of channels and/or gates of stacked devices, and isolation structures 18 may provide electrical isolation of source/drains of stacked devices.

In the depicted embodiment, the lower transistor 20L is a GAA transistor. For example, the lower transistor 20L has two channels provided by semiconductor layers 26L (also referred to as channel layers or channels), which are suspended over substrate 14 and extend between respective source/drains (e.g., epitaxial source/drains 62L). In some embodiments, the lower transistor 20L includes more or less channels (and thus more or less semiconductor layers 26L). Transistor 20L further has gate stack 90L disposed over its semiconductor layers 26L and between its epitaxial source/drains 62L, and inner spacers 54 are disposed between its gate stack 90L and its epitaxial source/drains 62L. Along a gate widthwise direction (e.g., in an X-Z plane), gate stack 90L is over top semiconductor layer 26L, between semiconductor layers 26L, and between bottom semiconductor layer 26L and substrate 14. Along a gate lengthwise direction (e.g., in a Y-Z plane), gate stack 90L wraps around semiconductor layers 26L. During operation of the GAA transistor, current can flow through semiconductor layers 26L and between epitaxial source/drains 62L. Semiconductor layers 26M (also referred to as dummy channel layers or dummy channels) are suspended over substrate 14 and extend between respective isolation structures 18, and isolation structures 17A are disposed between semiconductor layers 26M of device 12L/transistor 20L and semiconductor layers 26M of device 12U/transistor 20U.

In the depicted embodiment, the upper transistor 20U is also a GAA transistor. For example, the upper transistor 20U has two channels provided by semiconductor layers 26U (also referred to as channel layers or channels), which are suspended over substrate 14 and extend between respective source/drains (e.g., epitaxial source/drains 62U). In some embodiments, the upper transistor 20U includes more or less channels/semiconductor layers 26U. Transistor 20U further has gate stack 90U disposed over its semiconductor layers 26U and between its epitaxial source/drains 62U, gate stack 90U disposed between respective gate spacers 44, inner spacers 54 disposed between its gate stack 90U and its epitaxial source/drains 62U, and hard masks 92 disposed over the gate stack 90U. Along a gate widthwise direction, gate stack 90U is over top semiconductor layer 26U, between semiconductor layers 26U, and between bottom semiconductor layer 26U and semiconductor layer 26M. Along a gate lengthwise direction, gate stack 90U wraps around semiconductor layers 26U. During operation of the GAA transistor, current can flow through semiconductor layers 26U and between epitaxial source/drains 62U.

Fabricating stacked device structure 10A monolithically provides isolation structure 16A with isolation structures 17A and isolation structures 18 between channel regions and source/drain regions, respectively, of device 12L and device 12U. For example, a respective isolation structure 17A is between a channel region of the lower transistor 20L and a channel region of the upper transistor 20U (e.g., between channels and/or gates thereof), and isolation structures 18 are between source/drain regions of the lower transistor 20L and source/drain regions of the upper transistor 20U. In the depicted embodiment, the respective isolation structure 17A is between semiconductor layers 26M of the lower transistor 20L and the upper transistor 20U, and isolation structures 18 are between epitaxial source/drains 62L of the lower transistor 20L and epitaxial source/drains 62U of the upper transistor 20U. Accordingly, isolation structures 17A may function as channel isolation structures and/or gate isolation structures, and isolation structures 18 may function as source/drain isolation structures. Isolation structures 17A and isolation structures 18 may include a single layer or multiple layers. Isolation structures 17A and isolation structures 18 include a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). In some embodiments, the isolation structures 17A may include a first portion having a first composition and a second portion having a second composition, where the second composition is different than the first composition. Isolation structures 17A and isolation structures 18 may include the same or different materials and/or configurations. In the depicted embodiment, a thickness of isolation structures 17A is less than a thickness of isolation structures 18, and a configuration of isolation structures 17A is different than a configuration of isolation structures 18. In some embodiments, isolation structures 18 are formed by a portion of CESL 70L and ILD layer 72L, such as depicted.

Substrate 14, semiconductor layers 26U, semiconductor layers 26M, and semiconductor layers 26L include an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, substrate 14, semiconductor layers 26U, semiconductor layers 26M, and semiconductor layers 26L include silicon. In some embodiments, semiconductor layers 26U and semiconductor layers 26L include different semiconductor materials, such as silicon and silicon germanium, respectively, or vice versa. In some embodiments, substrate 14 is a semiconductor-on-insulator substrate, such as a silicon-on-insulator substrate, a silicon germanium-on-insulator substrate, or a germanium-on-insulator substrate. Substrate 14 (including mesas 14′ extending therefrom) may include various doped regions, such as p-wells and n-wells. The n-wells are doped with n-type dopants, such as phosphorus, arsenic, other n-type dopant, or a combination thereof. The p-wells are doped with p-type dopants, such as boron, indium, other p-type dopant, or a combination thereof.

Gate spacers 44 are disposed along sidewalls of upper portions of gate stacks 90U, inner spacers 54 are disposed under gate spacers 44 along sidewalls of gate stacks 90U and/or gate stacks 90L, and fin/mesa spacers may be disposed along sidewalls of mesas 14′. Inner spacers 54 are disposed between semiconductor layers 26 and between bottom semiconductor layers 26 and mesas 14′. Gate spacers 44, inner spacers 54, and fin spacers include a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). Gate spacers 44, inner spacers 44, and fin spacers may include different materials and/or different configurations (e.g., different numbers of layers). In some embodiments, gate spacers 44, inner spacers 54, fin spacers, or a combination thereof have a multilayer structure. In some embodiments, gate spacers 44 and/or fin spacers include more than one set of spacers, such as seal spacers, offset spacers, sacrificial spacers, dummy spacers, main spacers, or a combination thereof. The various sets of spacers may have different compositions.

Gate 90 is disposed between epitaxial source/drain stacks, where each epitaxial source/drain stack includes a respective epitaxial source/drain 62U, a respective epitaxial source/drain 62L, and a respective isolation structure 18 disposed therebetween. Epitaxial source/drains 62L and epitaxial source/drains 62U may have the same or different compositions and/or materials depending on configurations of their respective transistors. Epitaxial source/drains 62L and epitaxial source/drains 62U may be doped with n-type dopants and/or p-type dopants. In some embodiments, epitaxial source/drains 62L and/or epitaxial source/drains 62U include silicon that may be doped with carbon, phosphorous, arsenic, other n-type dopant, or a combination thereof (e.g., Si:C epitaxial source/drains, Si:P epitaxial source/drains, or Si:C:P epitaxial source/drains). In some embodiments, epitaxial source/drains 62L and/or epitaxial source/drains 62U include silicon germanium or germanium, which may be doped with boron, other p-type dopant, or a combination thereof (e.g., Si:Ge:B epitaxial source/drains). In the depicted embodiment, epitaxial source/drains 62L include silicon germanium doped with boron, and epitaxial source/drains 62U include silicon doped with phosphorous. In some embodiments, epitaxial source/drains 62L and/or epitaxial source/drains 62U include more than one epitaxial semiconductor layer, where the epitaxial semiconductor layers may include the same or different materials and/or the same or different dopant concentrations. In some embodiments, epitaxial source/drains 62L and/or epitaxial source/drains 62U include materials and/or dopants that achieve a desired tensile stress and/or compressive stress in adjacent channel regions (e.g., formed by semiconductor layers 26U and semiconductor layers 26L). As used herein, source/drain region, epitaxial source/drain, epitaxial source/drain feature, etc. may refer to a source of a device (e.g., the upper transistor 20U and/or the lower transistor 20L), a drain of a device (e.g., the upper transistor 20U and/or the lower transistor 20L), or a source and/or a drain of multiple devices.

ILD layer 72U and ILD layer 72L include a dielectric material, such as silicon oxide, carbon doped silicon oxide, silicon nitride, silicon oxynitride, tetraethyl orthosilicate (TEOS)-formed oxide, boron silicate glass (BSG), phosphosilicate glass (PSG), borophosphosilicate glass (BPSG), fluorosilicate glass (FSG), xerogel, aerogel, amorphous fluorinated carbon, parylene, benzocyclobutene-based (BCB) material, polyimide, other dielectric material, or a combination thereof. In some embodiments, ILD layer 72U and/or ILD layer 72L include a dielectric material having a dielectric constant that is less than a dielectric constant of silicon dioxide. CESL 70L and CESL 70U include a material different than a material of ILD layer 72U and ILD layer 72L, respectively. For example, where ILD layer 72U and ILD layer 72L include a low-k dielectric material that includes silicon and oxygen, CESL 70L and CESL 70U may include a material composed of silicon and nitrogen and/or carbon. In some embodiments, ILD layer 72U, ILD layer 72L, CESL 70L, CESL 70U, or a combination thereof may have a multilayer structure.

Gate dielectrics 78U and gate dielectrics 78L each include at least one gate dielectric layer. In accordance with the embodiments disclosed herein, gate dielectrics 78U and/or gate dielectrics 78L include a 2D dielectric material (e.g., 2D silica and/or 2D silicate) 79U and/or 79L disposed over respective semiconductor layers 26U, 26L. In some cases, both gate dielectrics 78U and 78L include a same 2D dielectric material. In other cases, each of the gate dielectrics 78U and 78L include different 2D dielectric materials. In some embodiments, gate dielectrics 78U and/or gate dielectrics 78L include a high-k dielectric layer, formed over the 2D dielectric material 79U, 79L, which includes a dielectric material having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, other high-k dielectric material, or a combination thereof. For example, gate dielectrics 78U and/or gate dielectrics 78L include a hafnium-based oxide (e.g., HfO₂) layer and/or a zirconium-based oxide (e.g., ZrO₂) layer. In some embodiments, the 2D dielectric material and/or the high-k dielectric layer may have a multilayer structure.

Gate electrodes 80U and gate electrodes 80L are disposed over gate dielectrics 78U and gate dielectrics 78L, respectively. Gate electrodes 80U and gate electrodes 80L each include at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or a combination thereof. In some embodiments, gate electrodes 80U and/or gate electrodes 80L include a work function layer. The work function layer is an electrically conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or a combination thereof. In some examples, the gate electrodes 80U and/or gate electrodes 80L do not include a work function layer, and instead the 2D dielectric material 79U, 79L, which may be doped during deposition of the 2D dielectric material 79U, 79L, may provide for dipole formation and WF tuning. In some embodiments, gate electrodes 80U and/or gate electrodes 80L include an electrically conductive bulk layer over a respective gate dielectric and/or work function layer. The bulk layer includes an electrically conductive material, such as Al, W, Cu, Ti, Ta, TiN, TaN, polysilicon, other metal(s), alloys thereof, or a combination thereof. In some embodiments, gate electrodes 80U and/or gate electrodes 80L include a barrier (blocking) layer over a respective work function layer and/or gate dielectric layer. The barrier layer includes a material that prevents or eliminates diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride (e.g., W₂N), titanium silicon nitride (TiSiN), tantalum silicon nitride (TaSiN), other metal nitride, or a combination thereof.

Hard masks 92 include a material that is different than ILD layer 72U and/or subsequently formed ILD layers to achieve etch selectivity during subsequent etching processes. In some embodiments, hard masks 92 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or a combination thereof. In some embodiments, hard masks 92 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or a combination thereof.

FIG. 1B provides a fragmentary cross-sectional view of a stacked device structure 10B, in portion or entirety, according to various aspects of the present disclosure. Stacked device structure 10B is fabricated sequentially, and thus may be referred to as a sequential stacked device structure. Since stacked device structure 10B is similar in many respects to stacked device structure 10A, similar features of stacked device structure 10B and stacked device structure 10A are identified by the same reference numerals for clarity and simplicity. For example, stacked device structure 10B includes device stack (e.g., upper device 12U vertically stacked over lower device 12L) disposed over substrate 14. Stacked device structure 10B includes an isolation structure 16B, instead of isolation structure 16A, between and separating the upper device 12U and the lower device 12L. In some embodiments, the upper device 12U and the lower device 12L are stacked back-to-front. For example, as described further below, isolation structure 16B may bond and/or attach a backside of the upper device 12U to a frontside of the lower device 12L, and isolation structure 16B may be referred to as a bonding layer/structure. FIG. 1B has been simplified for the sake of clarity to better understand the inventive concepts of the present disclosure. Additional features may be added in stacked device structure 10B, and some of the features described below may be replaced, modified, or eliminated in other embodiments of stacked device structure 10B.

In stacked device structure 10B, the lower device 12L and the upper device 12U include at least one electrically functional device, such as the lower transistor 20L and the upper transistor 20U, respectively (which are configured as GAA transistors). Device 12U includes various features and/or components, such as semiconductor layers 26U, gate spacers 44U, inner spacers 54U, epitaxial source/drains 62U, CESL 70U, ILD layer 72U, gate dielectrics 78U and gate electrodes 80U (which collectively form gate stacks 90U), and hard masks 92U. Device 12L also includes various features and/or components, such as mesas 14′ (e.g., extensions of substrate 14), semiconductor layers 26L, substrate isolation structures, gate spacers 44L, inner spacers 54L, epitaxial source/drains 62L, CESL 70L, ILD layer 72L, and gate dielectrics 78L and gate electrodes 80L (which collectively form gate stacks 90L). Stacked device structure 10B may further include source/drain contacts, such as upper source/drain contacts disposed in ILD layer 72U and on epitaxial source/drains 62U and lower source/drain contacts disposed in ILD layer 72L and on epitaxial source/drains 62L.

Because stacked device structure 10B is fabricated sequentially, isolation structure 16B is provided with an isolation structure 17B. Gate stacks 90U are separated from gate stacks 90L by isolation structure 17B, the upper device 12U and/or the lower device 12L may not have semiconductor layers 26M (as shown in the embodiment of FIG. 1A), and epitaxial source/drains 62U are separated from epitaxial source/drains 62L by isolation structure 17B. Isolation structure 17B is thus between channel regions and source/drain regions, respectively, of the lower device 12L and the upper device 12U, and isolation structure 17B may provide electrical isolation of both channels/gates and source/drains of stacked devices. For example, isolation structure 17B extends continuously, without interruption between channel regions and source/drain regions of the lower transistor 20L and the upper transistor 20U. Isolation structure 17B may include a single layer or multiple layers. Isolation structure 17B includes a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). In some embodiments, the isolation structure 17B may include a first portion having a first composition and a second portion having a second composition, where the second composition is different than the first composition.

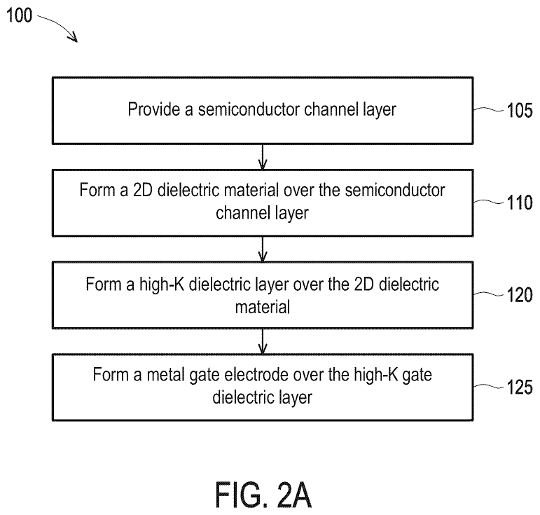

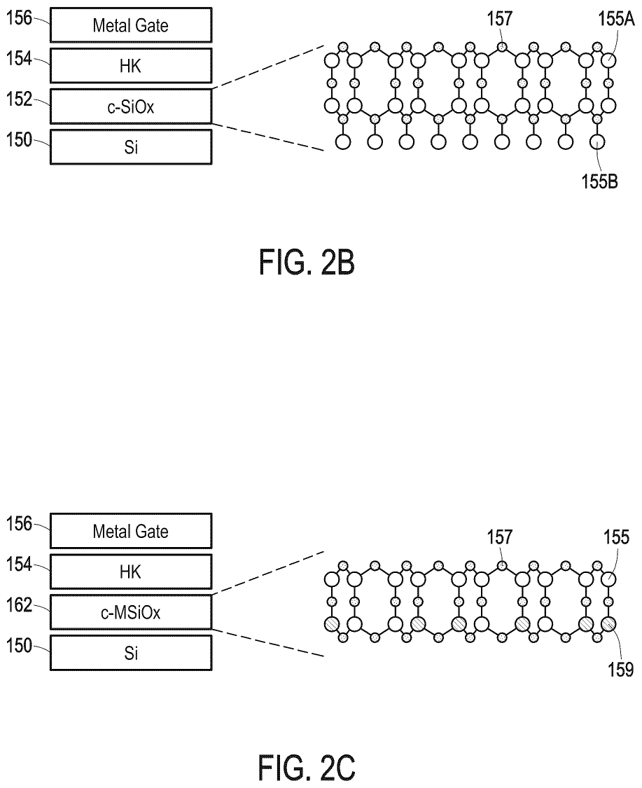

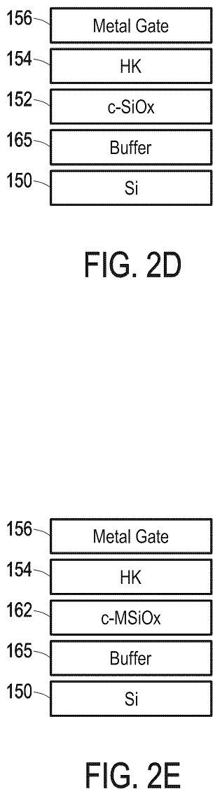

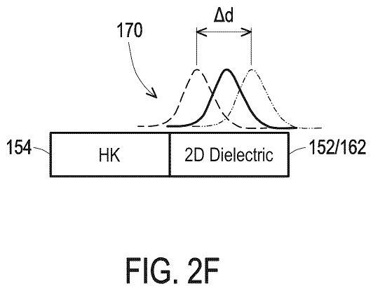

Referring to FIG. 2A, illustrated therein is a flow chart of a method 100, in portion or entirety, for forming a gate structure of a transistor, according to various aspects of the present disclosure. The method 100 may be implemented in the formation of a gate structure for various types of transistors such as planar transistors, FinFETs, and/or GAA transistors including nanosheet transistors and nanowire transistors. More particularly, in some embodiments, the method 100 may be implemented in the formation of a gate structure for a stacked transistor structure (e.g., such as the stacked device structure 10A and the stacked device structure 10B, discussed above). FIGS. 2B, 2C, 2D, and 2E illustrate embodiments of various gate structures that may be formed in correspondence with the method 100 of FIG. 2A, according to various aspects of the present disclosure. FIG. 2F illustrates a dipole profile corresponding to the embodiments of the gate structures disclosed herein, according to some aspects of the present disclosure.

In FIGS. 2A-2E, method 100 at block 105 includes providing a semiconductor channel layer 150. The semiconductor channel layer 150 may include a Si-, SiGe-, or Ge-based material layer present in planar transistors, FinFETs, and/or GAA transistors including nanosheet transistors and nanowire transistors. In some cases, the semiconductor channel layer 150 may include a channel layer of a stacked transistor structure (e.g., such as the stacked device structure 10A and the stacked device structure 10B, discussed above). In the illustrated example, the semiconductor channel layer 150 includes a silicon channel layer. In some embodiments, the semiconductor channel layer 150 may be exposed (or provided, as in block 105 of the method 100) by way of a channel release process, where a dummy semiconductor layer (e.g., such as SiGe) is selectively removed to form gaps between adjacent semiconductor channel layers (e.g., such as the semiconductor channel layer 150).

In FIGS. 2A-2E, the method 100 at block 110 includes forming a 2D dielectric material 152 (FIGS. 2B, 2D) or a 2D dielectric material 162 (FIG. 2C, 2E) over the semiconductor channel layer 150 or over an optional buffer layer 165, as discussed below. In some embodiments, the 2D dielectric material 152 (FIG. 2B, 2D) includes crystalline 2D silica (c-SiOx), and the 2D dielectric material 162 (FIG. 2C, 2E) includes a crystalline 2D silicate (c-MSiOx, where ‘M’ is a metal). In various embodiments, the 2D dielectric materials 152, 162 have a hexagonal crystal symmetry. It is also noted that 2D silica consists of X-member rings, where X is between 3 and 9, without forming grain boundaries and negatively impacting device performance. By way of example, the structure of the 2D dielectric materials 152, 162 may be detected by an appropriate metrology technique such as using electron diffraction, X-ray diffraction (XRD), Raman spectroscopy, transmission electron microscopy (TEM), scanning tunneling microscopy (STM), or other appropriate metrology technique. In various embodiments, the 2D dielectric materials 152, 162 have a thickness of between about 0.5 nm (e.g., for a bilayer structure) to about 2 nm (e.g., for multi-2D layers). In some embodiments, and as shown in FIGS. 2D and 2E, the buffer layer 165 (or adhesion layer 165) may optionally be formed over the semiconductor channel layer 150 prior to forming the 2D dielectric material 152, 162. In such cases, the 2D dielectric material 152, 162 may then be formed over the buffer layer 165. In an example, the buffer layer 165 may include a crystalline oxide layer or a crystalline nitride layer, and the buffer layer 165 may be formed using chemical vapor deposition (CVD), atomic layer deposition (ALD), physical vapor deposition (PVD), or other appropriate process.

Whether forming the 2D dielectric materials 152, 162 over the semiconductor channel layer 150 (FIGS. 2B, 2C) or over the buffer layer 165 (FIGS. 2D, 2E), in various examples the 2D dielectric materials 152, 162 may be formed using a variety of methods such as direct growth over the semiconductor channel layer 150 (or direct growth over the buffer layer 165) via CVD, ALD, PVD, or via growth on a separate substrate and subsequent transfer to the semiconductor channel layer 150 (or transfer to the buffer layer 165). In some cases, and to enable direct growth of the 2D dielectric materials 152, 162 over the semiconductor channel layer 150 (or direct growth over the buffer layer 165), the amount of Si introduced during deposition should be carefully controlled. Control of the amount of Si introduced during deposition also helps to avoid formation of 3D silica, which may result from the introduction of too much Si during deposition. In some embodiments, the deposition temperature used to form the 2D dielectric materials 152, 162 may be between about 350-750 degrees Celsius. In other embodiments, the 2D dielectric materials 152, 162 may be initially deposited at a lower temperature (e.g., such as room temperature) and then annealed at a higher temperature (e.g., such as between about 350-750 degrees Celsius).

When forming the 2D dielectric material 152 (FIG. 2B, 2D) including crystalline 2D silica (c-SiOx), for example by one of the methods discussed above, a silicon source and an oxygen source may be used to co-deposit silicon and oxygen atoms over the semiconductor channel layer 150 (or over the buffer layer 165) to form the 2D silica (c-SiOx). By way of example, FIG. 2B (right-hand side) illustrates a ball-and-stick model of the 2D silica (c-SiOx) formed over the semiconductor channel layer 150. As shown, the hexagonal crystal structure of the 2D silica (c-SiOx) includes silicon atoms 155A and oxygen atoms 157. A top layer of silicon atoms 155B of the crystalline structure of the semiconductor channel layer 150 is also illustrated, where the 2D silica (c-SiOx) bonds to the semiconductor channel layer 150, in this example. In various cases, the bonding between the 2D silica (c-SiOx) and the semiconductor channel layer 150 (or the buffer layer 165) may include covalent bonding and/or van der Waals type bonds.

After formation of the 2D silica (c-SiOx), in some embodiments, metal ions may be introduced into the 2D dielectric material 152 for dipole formation. As an option, a metal oxide, metal nitride, or other dipole-inducing layer may be formed over the 2D dielectric material 152 and a thermal diffusion process (e.g., an anneal) may be performed to drive ions from the dipole-inducing layer into the 2D silica (c-SiOx) to form a silicate and to form a dipole substantially within the silicate. In accordance with some embodiments, the metal used to form the silicate may tend to locate (bond) itself near one-side of the 2D silicate (e.g., a top-side or bottom-side of the 2D silicate) until substantially all available sites are occupied by the metal, thereby creating a controllable dipole and thus provide for controllable Vt tuning of the transistor. As previously noted, formation of the dipole may be used for modulating a transistor Vt by tuning a work function (WF) of the transistor. In some cases, after formation of the dipole within the silicate, any remaining material of the dipole-inducing layer may be removed from over the 2D dielectric material 152 prior to subsequent processing. For avoidance of doubt, in some cases, the dipole formation step (e.g., including deposition of a dipole-inducing layer over the 2D dielectric material 152 and a thermal diffusion process) may be omitted if WF/Vt tuning is not desired. Nevertheless, implementation of the 2D dielectric material 152 will still provide for enhanced device performance (e.g., due to enhanced EOT scaling, enhanced interface with the underlying semiconductor channel layer 150, and the crystalline structure of the 2D dielectric material 152).

When forming the 2D dielectric material 162 (FIG. 2C, 2E) including a crystalline 2D silicate (c-MSiOx, where ‘M’ is a metal), for example by one of the methods discussed above, a silicon source, an oxygen source, and a metal source may be used to co-deposit silicon, oxygen, and metal atoms over the semiconductor channel layer 150 (or over the buffer layer 165) to form the 2D silicate (c-MSiOx, where ‘M’ is a metal). By way of example, FIG. 2C (right-hand side) illustrates a ball-and-stick model of the 2D silicate (c-MSiOx, where ‘M’ is a metal) formed over the semiconductor channel layer 150. As shown, the hexagonal crystal structure of the 2D silicate (c-MSiOx) includes silicon atoms 155, oxygen atoms 157, and metal atoms 159. The metal atoms 159, in various cases, may include metal elements suitable for inducing a dipole moment such as La, Al, Sc, Y, Ti, Sr, Er, Mg, Ta, another dipole-inducing layer, or combinations thereof. In some embodiments, the 2D silicate (c-MSiOx) bonds to the semiconductor channel layer 150 (or the buffer layer 165) via covalent bonding and/or van der Waals type bonds.

A quantity and location of the metal atoms 159 introduced by the metal source may be selectively tuned, for example by appropriate selection of deposition parameters associated with deposition of the 2D dielectric material 162, to form a dipole substantially within the silicate and to selectively modulate a transistor Vt (e.g., by WF tuning). In some embodiments, introduction of the metal atoms 159 by the metal source is controlled by setting a prescribed dosage during deposition of the 2D silicate (c-MSiOx). By way of example, this is performed in contrast to introduction of metal ions into the 2D dielectric material 162 by a thermal diffusion process. In accordance with some embodiments, the metal atoms 159 introduced into the 2D silicate (the 2D dielectric material 162) may tend to locate (bond) themselves near one-side of the 2D dielectric material 162 (e.g., a top-side or bottom-side of the 2D dielectric material 162) until substantially all available sites are occupied by the metal, thereby creating a controllable dipole and thus provide for controllable Vt tuning of the transistor. In cases where the 2D dielectric material 162 (FIG. 2C, 2E) including the crystalline 2D silicate (c-MSiOx) is formed by co-deposition of silicon atoms 155, oxygen atoms 157, and metal atoms 159 over the semiconductor channel layer 150 (or over the buffer layer 165), the separate dipole formation step (e.g., including deposition of a dipole-inducing layer over the 2D dielectric material 162 and a thermal diffusion process) need not be performed.

In FIGS. 2A-2E, the method 100 at block 120 includes forming a high-K dielectric layer 154 over the 2D dielectric material 152 (FIGS. 2B, 2D) or over the 2D dielectric material 162 (FIG. 2C, 2E). The high-K dielectric layer 154 may include a Hf-based dielectric layer (e.g., HfO₂), a Zr-based dielectric layer (e.g., ZrO₂), or another suitable high-K dielectric layer. Generally, in various cases, the high-K dielectric layer 154 may include HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, other high-k dielectric material, or a combination thereof. In some embodiments, the high-K dielectric layer 154 may be deposited by ALD, CVD, PVD, or another suitable deposition process. The high-K dielectric layer 154, in some examples, may have a thickness of about 1-5 nm.

In FIGS. 2A-2E, the method 100 at block 125 includes forming a metal gate electrode 156 over the high-K dielectric layer 154. The metal gate electrode 156 includes an electrically conductive material such as Al, Cu, Ti, Ta, W, Mo, Co, TaN, NiSi, CoSi, TiN, WN, TiAl, TiAlN, TaCN, TaC, TaSiN, other electrically conductive material, or a combination thereof. In some cases, the metal gate electrode 156 may be formed using ALD, PVD, CVD, electron beam (e-beam) evaporation, and/or other suitable process. In an example, the metal gate electrode 156 may have a thickness of about 0.5-5 nm. In some embodiments, the metal gate electrode 156 may optionally include a work function layer, as previously described. However, in some cases, the metal gate electrode 156 does not include a work function layer, and instead the 2D dielectric material 152, 162 is relied upon to provide for dipole formation and WF tuning, as discussed above. In some embodiments, a barrier (blocking) layer may be formed over the high-K dielectric layer 154 prior to formation of the metal gate electrode 156. Such a barrier layer, by way of example, may include metal and nitrogen, such as titanium nitride, tantalum nitride, tungsten nitride (e.g., W₂N), titanium silicon nitride (TiSiN), tantalum silicon nitride (TaSiN), other metal nitride, or a combination thereof.

With reference to FIG. 2F, illustrated there is a dipole profile 170 that may be formed as a result of the method 100, in accordance with some embodiments. For example, the dipole profile 170 may correspond to a quantity and location of metal atoms and/or metal ions within the 2D dielectric materials 152, 162 which are responsible for formation of the dipole within the 2D dielectric materials 152, 162. As such, the dipole profile 170 may also be indicative of a relative dipole strength within the 2D dielectric materials 152, 162. Generally, the dipole profile 170 may be disposed substantially within the 2D dielectric materials 152, 162. However, in various embodiments, the dipole profile 170 may not be centered within the 2D dielectric materials 152, 162, being instead shifted towards the overlying high-K dielectric layer 154 or towards the underlying semiconductor channel layer 150 (or the underlying buffer layer 165). As such, and depending on various deposition parameters, the dipole profile 170 may be disposed nearer a top-side or a bottom-side of the 2D dielectric material 152, 162, such that a possible location of the peak of the dipole profile 170 lies within a space of less than about 1 nm (e.g., where a spread Δd of the peak of the dipole profile 170 is less than about 1 nm). In some examples, the dipole profile 170 may be detected by an appropriate metrology technique such as using energy-dispersive X-ray spectroscopy (EDS), electron energy loss spectroscopy (EELS), secondary ion mass spectrometry (SIMS), or other appropriate metrology technique.

FIGS. 2A-2F have been simplified for the sake of clarity to better understand the inventive concepts of the present disclosure. Additional steps may be provided before, during, and after the method 100, and some of the steps described may be moved, replaced, or eliminated for additional embodiments of the method 100. Additional features may be added in FIGS. 2B-2F, and some of the features described below may be replaced, modified, or eliminated in other embodiments of FIG. 2B-2F.

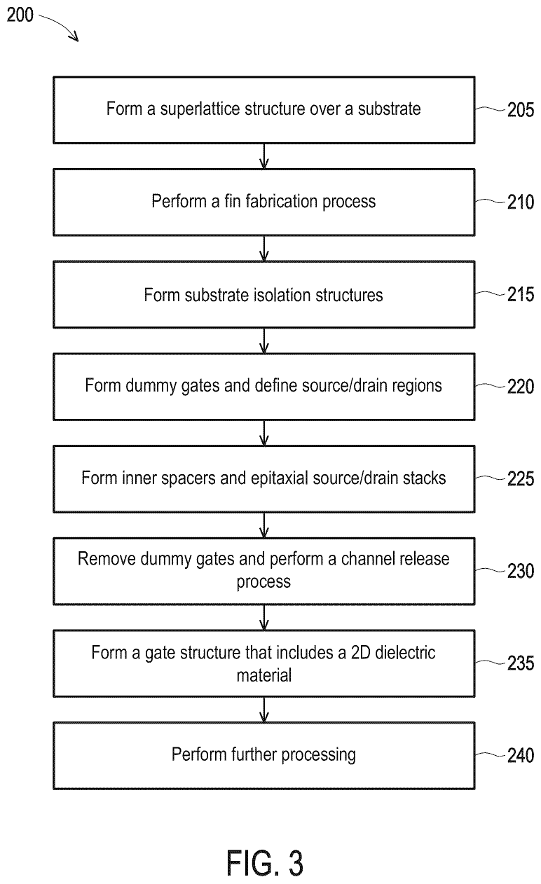

Referring now to FIG. 3, illustrated therein is a flow chart of a method 200 for monolithically fabricating a stacked device structure, such as stacked device structure 10A of FIG. 1A, that implements the methods of forming a gate structure of FIGS. 2A-2F, according to various aspects of the present disclosure. The method 200 of FIG. 3 has been simplified for the sake of clarity to better understand the inventive concepts of the present disclosure. Additional steps may be provided before, during, and after method 200, and some of the steps described may be moved, replaced, or eliminated for additional embodiments of method 200.

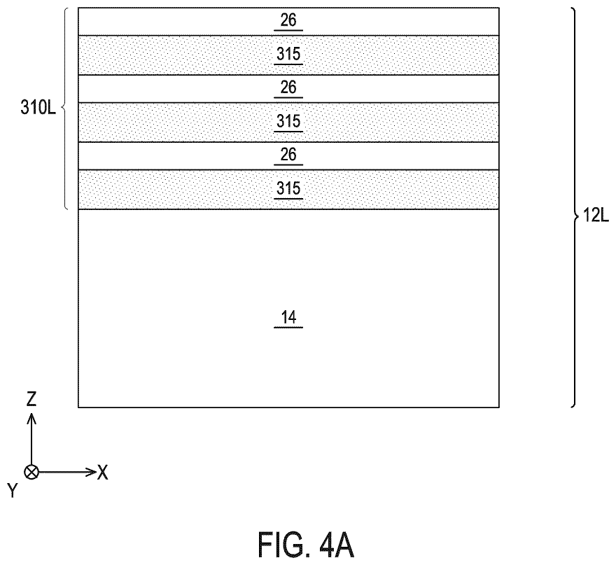

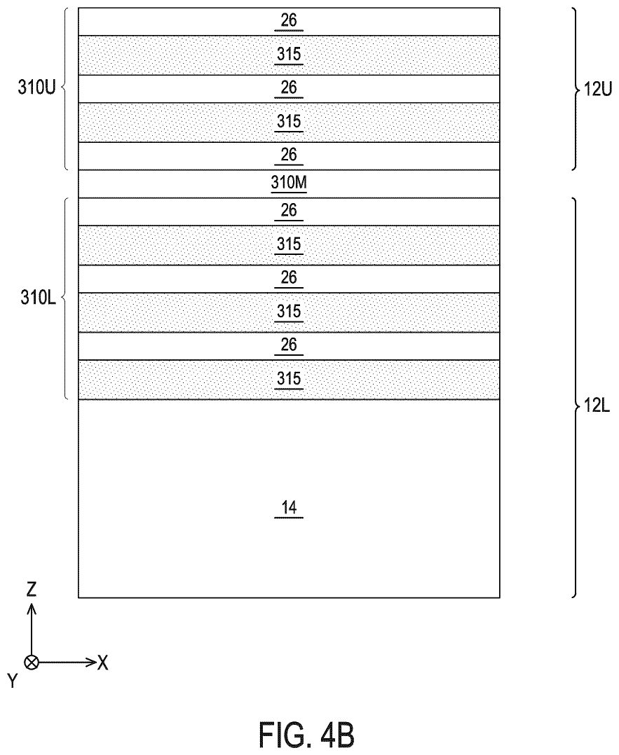

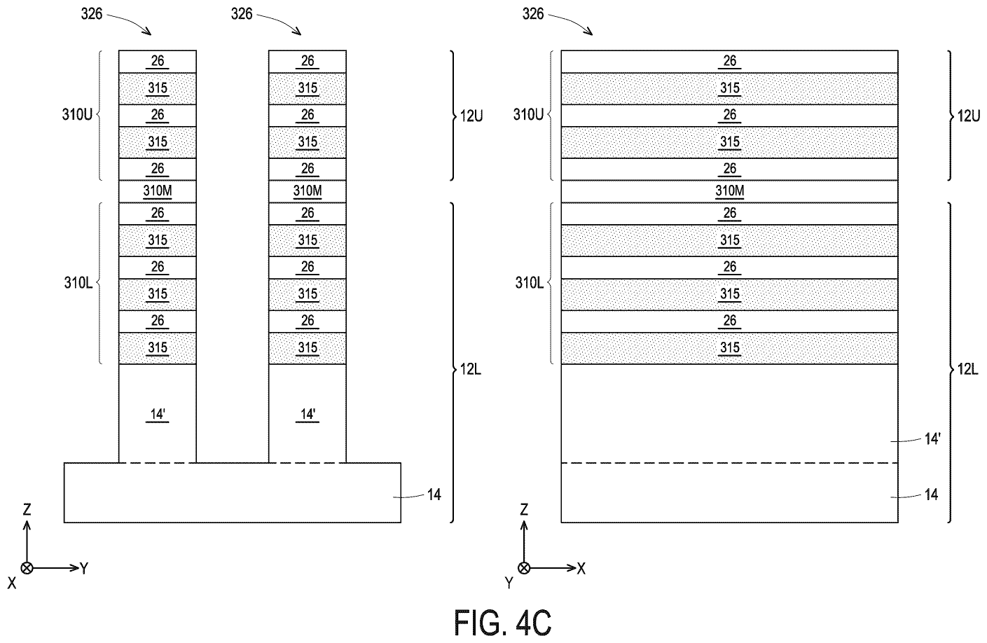

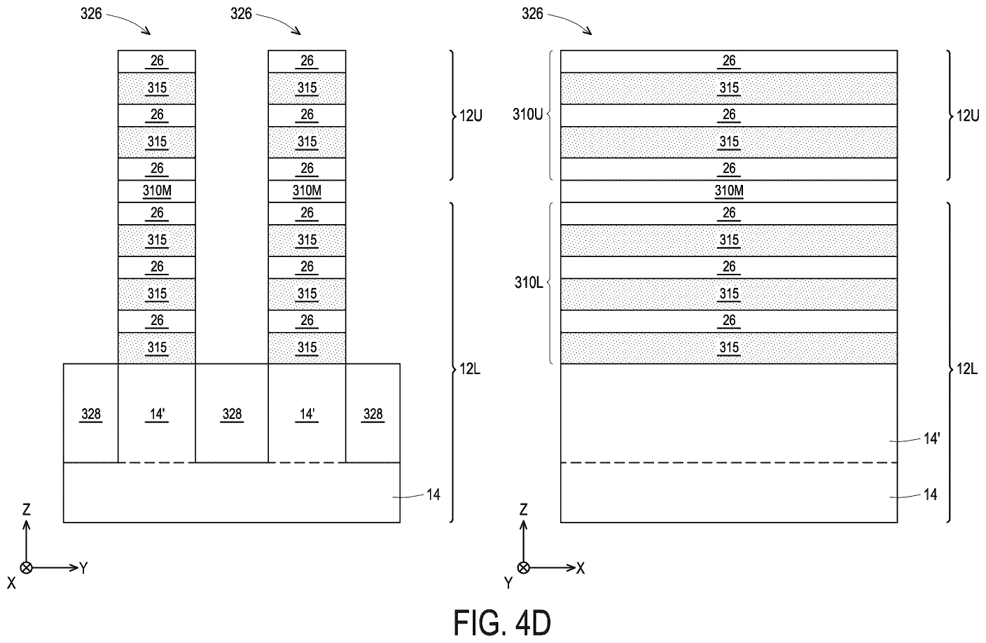

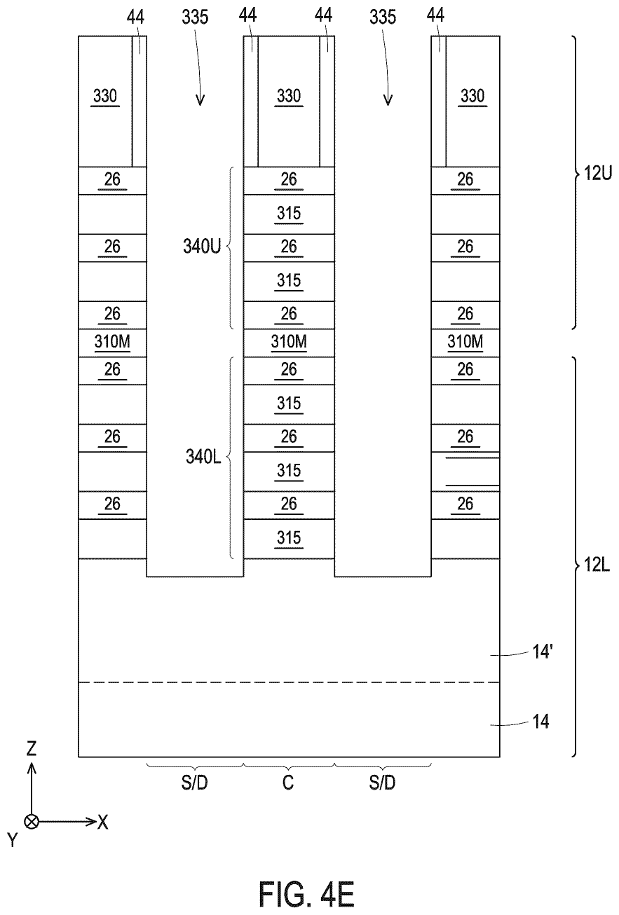

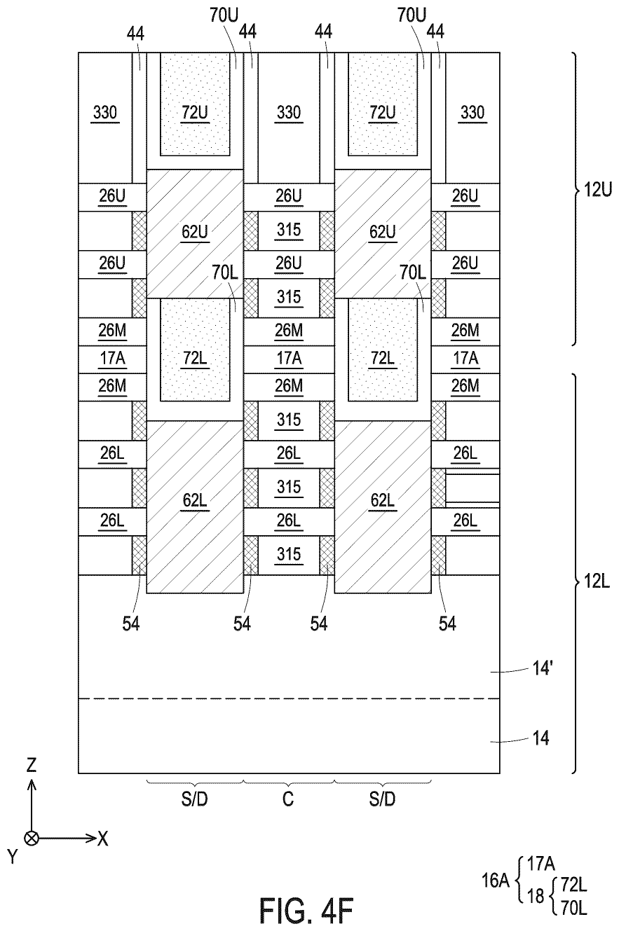

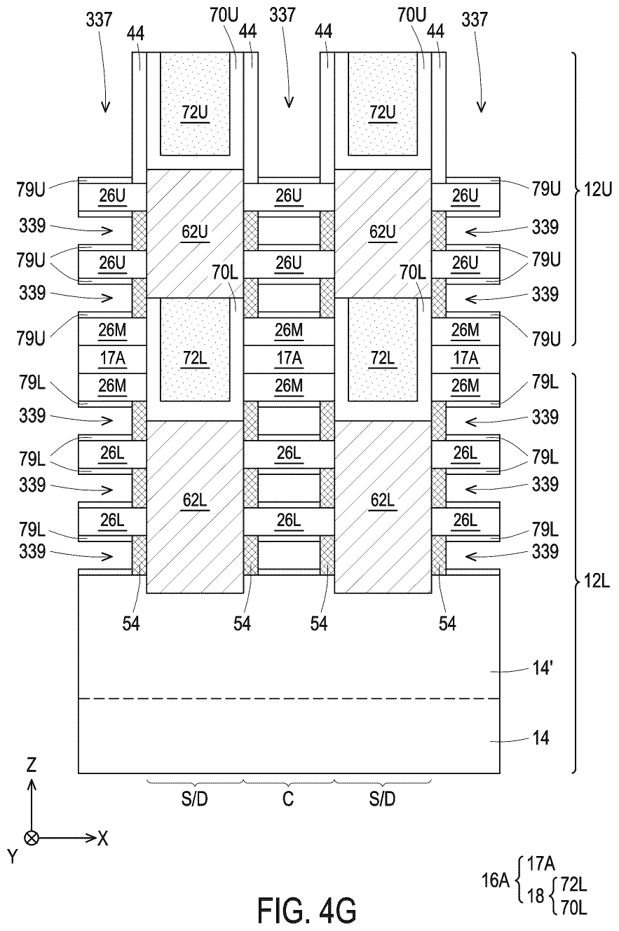

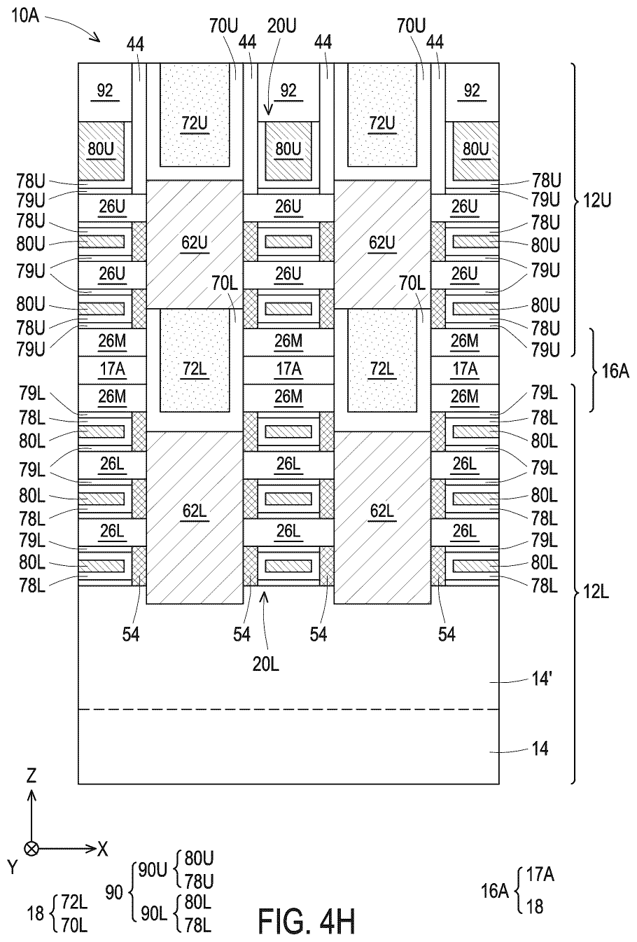

FIGS. 4A-4H are cross-sectional views of stacked device structure 10A, in portion or entirety, at various monolithic fabrication stages, such as those associated with method 200 of FIG. 3 when implementing the methods of forming a gate structure of FIGS. 2A-2F, according to various aspects of the present disclosure. FIGS. 4A-4H have been simplified for the sake of clarity to better understand the inventive concepts of the present disclosure. Additional steps may be provided before, during, and after the monolithic fabrication steps of FIGS. 4A-4H, and some of the steps described may be moved, replaced, or eliminated for additional embodiments of the monolithic fabrication steps of FIGS. 4A-4H. Additional features may be added in stacked device structure 10A of FIGS. 4A-4H, and some of the features described below may be replaced, modified, or eliminated in other embodiments of stacked device structure 10A of FIGS. 4A-4H.

Referring to FIGS. 4A and 4B, and in an embodiment of block 205, fabricating stacked device structure 10A includes forming a superlattice structure over a substrate 14. Initially, a semiconductor layer stack 310L (e.g., for a device 12L) is formed over the substrate 14. Thereafter, a middle sacrificial layer 310M is formed over the semiconductor layer stack 310L, and then a semiconductor layer stack 310U (e.g., for a device 12U) is formed over the middle sacrificial layer 310M. Semiconductor layer stack 310L and semiconductor layer stack 310U each include respective semiconductor layers 26 and respective semiconductor layers 315. Semiconductor layers 315 and semiconductor layers 26 are stacked vertically (e.g., along the z-direction) in an interleaving and/or alternating configuration from a top surface of substrate 14. A composition of semiconductor layers 315 and a composition of semiconductor layers 26 are different to achieve etching selectivity and/or different oxidation rates during processing. For example, semiconductor layers 315 and semiconductor layers 26 include different materials, constituent atomic percentages, constituent weight percentages, thicknesses, other characteristics, or a combination thereof to achieve desired etching selectivity. In the depicted embodiment, semiconductor layers 26 include silicon (e.g., to provide channel layers for each of the devices 12L, 12U), and semiconductor layers 315 include silicon germanium. With such compositions, semiconductor layers 315 may have a first etch rate to an etchant, semiconductor layers 26 may have a second etch rate to the etchant, and the first etch rate and the second etch rate are different. As shown, the middle sacrificial layer 310M serves to vertically separate the semiconductor layer stack 310L from the semiconductor layer stack 310U. The middle sacrificial layer 310M may be composed of germanium and may have a different germanium content as compared to the semiconductor layers 315. In some embodiments, a germanium content of the middle sacrificial layer 310M may be greater than a germanium content of the semiconductor layers 315 such that an entirety of the middle sacrificial layer 310M may be selectively removed during the formation of inner spacers, as discussed below.

After forming the superlattice structure (block 205), the method 200 proceeds to block 210, where a fin fabrication process is performed. With reference to FIGS. 4B and 4C, in an embodiment of block 210, a fin fabrication process is performed to form fins 326 (also referred to as fin structures, fin elements, etc.) extending from substrate 14. Fins 326 extend substantially parallel to one another along an x-direction, having a length in the x-direction, a width in a y-direction, and a height in a z-direction. Each of fins 326 include a substrate portion (e.g., a respective mesa 14′), a first semiconductor layer stack portion disposed over the substrate portion (e.g., a respective portion of semiconductor layer stack 310L), an isolation portion disposed over the first semiconductor layer stack portion (e.g., a respective portion of middle sacrificial layer 310M), and a second semiconductor layer stack portion (e.g., a respective portion of semiconductor layer stack 310U) disposed over the isolation portion. Fabrication of fins 326 may include performing a lithography process and/or etching process to pattern a semiconductor layer stack precursor (e.g., semiconductor layer stack 310U and semiconductor layer stack 310L separated by middle sacrificial layer 310M) and/or substrate 14. In some embodiments, fins 326 are formed by a multiple patterning process, such as a double patterning lithography (DPL) process (for example, a lithography-etch-lithography-etch (LELE) process, a self-aligned double patterning (SADP) process, a spacer-is-dielectric (SID) SADP process, other double patterning process, or a combination thereof), a triple patterning process (for example, a lithography-etch-lithography-etch-lithography-etch (LELELE) process, a self-aligned triple patterning (SATP) process, other triple patterning process, or a combination thereof), other multiple patterning process (for example, a self-aligned quadruple patterning (SAQP) process), or a combination thereof.

The method 200 proceeds to block 215, where substrate isolation structures are formed. With reference to FIGS. 4C and 4D, in an embodiment of block 215, substrate isolation structures 328 are formed in trenches between fins 326. Substrate isolation structures 328 fill lower portions of the trenches and surround portions of fins 326. Portions of fins 326 that extend above top surfaces of the substrate isolation structures 328 may be referred to as fin active regions. Substrate isolation structures 328 electrically isolate active device regions and/or passive device regions. Substrate isolation structures 328 include silicon oxide, silicon nitride, silicon oxynitride, other suitable isolation material (e.g., including silicon, oxygen, nitrogen, carbon, etc.), or a combination thereof. Substrate isolation structures 328 may have a multilayer structure. For example, substrate isolation structures 328 may include a bulk dielectric (e.g., an oxide layer) over a dielectric liner (e.g., silicon nitride, silicon oxide, silicon oxynitride, silicon oxycarbonitride, or a combination thereof). In another example, substrate isolation structures 328 may include a bulk dielectric over a doped liner, such as a BSG liner and/or a PSG liner. Dimensions and/or characteristics of substrate isolation structures 328 are configured to provide shallow trench isolation (STI) structures, deep trench isolation (DTI) structures, local oxidation of silicon (LOCOS) structures, other suitable isolation structures, or a combination thereof. In the depicted embodiment, substrate isolation structures 328 may be STI structures.

Substrate isolation structures 328 may be formed by depositing a liner layer (e.g., a dielectric layer) that partially fills the trenches, depositing an oxide material over the liner layer that fills remainders of the trenches, performing a planarization process, and recessing and/or etching back substrate isolation structures 328, such that fins 326 protrude therefrom. The planarization process (e.g., CMP) may be performed until reaching and exposing a planarization stop layer. In some embodiments, the planarization process removes mask layers, any of the oxide material, any of the liner layer, or a combination thereof that are above and/or over top surfaces of fins 326. Remainders of the liner layer and the oxide material may form liners and bulk dielectrics, respectively, of substrate isolation structures 328.

The method 200 proceeds to block 220, where dummy gates are formed and source/drain regions are defined. With reference to FIGS. 4D and 4E, in an embodiment of block 220, dummy gate stacks 330 are formed over portions of fins 326, gate spacers 44 are formed along sidewalls of the dummy gate stacks 330, and source/drain recesses 335 are defined. Dummy gate stacks 330 extend lengthwise in a direction that is different than (e.g., orthogonal to) the lengthwise direction of fins 326. For example, dummy gate stacks 330 extend along the y-direction, having a length in the y-direction, a width in the x-direction, and a height in the z-direction. In the X-Z plane, dummy gate stacks 330 are disposed over tops of channel regions (C) of fins 326 and/or stacked device structure 10A, and dummy gate stacks 330 are disposed between source/drain regions (S/D) of fins 326 and/or stacked device structure 10A. In the Y-Z plane, dummy gate stacks 330 may be disposed on tops and sidewalls of fins 326, and dummy gate stacks 330 may wrap channel regions. Dummy gate stacks 330 may include a dummy gate dielectric, a dummy gate electrode, a hard mask, other suitable layers (e.g., a capping layer, an interface layer, a diffusion layer, a barrier layer, etc.), or a combination thereof. The dummy gate dielectric includes a dielectric material, such as silicon oxide, a high-K dielectric material, other suitable dielectric material, or a combination thereof. The dummy gate electrode includes a suitable dummy gate material, such as polysilicon. The hard mask includes suitable hard mask material, such as silicon nitride.

Source/drain recesses 335 may be formed by performing an etching process that removes semiconductor layer stack 310U, middle sacrificial layer 310M, and semiconductor layer stack 310L in source/drain regions of fins 326, thereby exposing mesas 14′. The etching process further removes some, but not all, of mesas 14′, such that source/drain recesses 335 extend below top surfaces of substrate isolation structures 328. Each source/drain recess 335 has respective sidewalls formed by respective remaining portions of semiconductor layer stack 310U, middle sacrificial layer 310M, and semiconductor layer stack 310L in channel regions of fins 326 and a bottom formed by a respective mesa 14′. In the depicted embodiment, after forming source/drain recesses 335, each channel region includes an upper channel portion 340U (e.g., formed by a remainder of semiconductor layer stack 310U) and a lower channel portion 340L (e.g., formed by a remainder of semiconductor layer stack 310L) separated by a portion of the middle sacrificial layer 310M. In some embodiments, the etching process removes some, but not all, of semiconductor layer stacks 310L, and source/drain recesses 335 have bottoms formed by semiconductor layers 26 or semiconductor layers 315. In some embodiments, the etching process stops at mesas 14′, and source/drain recesses 335 do not extend below substrate isolation structures 328. The etching process is a dry etch, a wet etch, other suitable etch, or a combination thereof. In some embodiments, the etching process is a multistep etch process.

The method 200 proceeds to block 225, where inner spacers and epitaxial source/drain stacks are formed. With reference to FIGS. 4E and 4F, in an embodiment of block 225, inner spacers 54 are formed under gate spacers 44 along sidewalls of semiconductor layers 315. Inner spacers 54 replace portions of semiconductor layers 315 under gate spacers 44, separate semiconductor layers 26 from one another, and separate bottom semiconductor layers 26 from mesas 14′. Forming inner spacers 54 may include a first etching process, a deposition process, and a second etching process. The first etching process selectively etches semiconductor layers 315 with negligible etching of semiconductor layers 26 and mesas 14′. The first etching process is configured to laterally etch semiconductor layers 315 to reduce lengths thereof along the x-direction, thereby forming gaps between semiconductor layers 26 and between mesas 14′ and semiconductor layers 26 that separate adjacent semiconductor layers 26 and separate mesas 14′ and adjacent semiconductor layers 26. In some embodiments, the gaps laterally extend under dummy gate stacks 330. The deposition process forms a spacer layer that at least partially fills (and may completely fill) the gaps, and the second etching process selectively etches the spacer layer with negligible etching of semiconductor layers 26 and mesas 14′, such that remainders of the spacer layer form inner spacers 54. It is further noted that the process used to form the inner spacers 54 also serves to remove the middle sacrificial layer 310M, and the spacer layer material (used to form the inner spacers 54) may also be formed within a space left vacant by removal of the middle sacrificial layer 310M to form the isolation structures 17A. In some embodiments, the inner spacers 54 and the isolation structures 17A include a dielectric material that includes silicon, oxygen, carbon, nitrogen, other suitable dielectric constituent, or a combination thereof. For example, the spacer layer may include a silicon nitride layer, a silicon carbonitride layer, a silicon oxycarbonitride layer, a silicon oxycarbide layer, or a combination thereof.

In a further embodiment of block 225, epitaxial source/drain stacks are formed in source/drain recesses 335, and a dielectric layer (e.g., CESL 70U and ILD layer 72U) may be formed over the epitaxial source/drain stacks. Each epitaxial source/drain stack includes a respective epitaxial source/drain 62U and a respective epitaxial source/drain 62L separated by a respective source/drain isolation structure, such as isolation structure 18 (e.g., CESL 70L and ILD layer 72L). Epitaxial source/drain stacks may be formed by filling a bottom/lower portion of source/drain recesses 335 with one or more epitaxial semiconductor materials to form epitaxial source/drains 62L adjacent to semiconductor layers 26 of lower channel portion 340L, filling a middle portion of source/drain recesses 335 with one or more dielectric materials (e.g., CESL 70L and ILD layer 72L) to form isolation structures 18 adjacent to isolation structures 17A (i.e., channel isolation structures), and filling a top/upper portion of source/drain recesses 335 with one or more epitaxial semiconductor materials to form epitaxial source/drains 62U adjacent to semiconductor layers 26 of upper channel portion 340U. Semiconductor layers 26 extending between epitaxial source/drains 62U may be referred to as upper semiconductor layers 26U, semiconductor layers 26 extending between epitaxial source/drains 62L may be referred to as lower semiconductor layers 26L, and semiconductor layers 26 extending between isolation structures 18 may be referred to as middle semiconductor layers 26M. Epitaxial source/drains 62L and epitaxial source/drains 62U are formed by any suitable epitaxial deposition and/or growth process. Isolation structures 18 may be formed by depositing a CESL over epitaxial source/drains 62L, depositing an ILD layer over the CESL, and etching back the CESL and/or the ILD layer to expose semiconductor layers 26 of upper channel portion 340U that will provide channels for device 12U (e.g., semiconductor layers 26U).

In the depicted embodiment, isolation structure 16A, which separates and/or electrically isolates device 12L and device 12U, is provided by isolation structures 17A (i.e., channel isolation structures and/or gate isolation structures) and isolation structures 18 (i.e., source/drain isolation structures). Isolation structures 17A are disposed between isolation structures 18. Isolation structures 18 extend to a distance above a dummy semiconductor layer of channel portion 340U (e.g., semiconductor layer 26M thereof) and a distance below a bottom active semiconductor layer of channel portion 340U (e.g., bottom semiconductor layer 26U thereof), and isolation structures 18 extend to a distance below a dummy semiconductor layer of channel portion 340L (e.g., semiconductor layer 26M thereof) and a distance above a top active semiconductor layer of channel portion 340L (e.g., top semiconductor layer 26L thereof). The present disclosure contemplates other configurations of isolation structures 18, such as where isolation structures 18 are disposed between isolation structures 17A, but not semiconductor layers 26M (i.e., semiconductor layers 26M extend between respective epitaxial source/drains, instead of isolation structures 18).

The method 200 proceeds to block 230 where dummy gate stacks are removed and a channel release process is performed. With reference to FIGS. 4F and 4G, in an embodiment of block 230, dummy gate stacks 330 are initially removed to form gate openings 337 (e.g., by a selective etching process). After forming the gate openings 337, semiconductor layers 315, which have been exposed by formation of the gate openings 337, are selectively removed to form gaps/openings 339 between semiconductor layers 26 and between semiconductor layers 26 and mesas 14′ (e.g., by a selective etching process). As a result of forming the gaps/openings 339, the top semiconductor channel layers 26U and the bottom semiconductor channel layers 26L are exposed and ready for subsequent formation of a gate structure thereupon, where the gate structure includes a 2D dielectric material, in accordance with the embodiment disclosed herein. In particular, and in some embodiments, the subsequently formed gate structure, or portions thereof, may fill the gaps/openings 339, such that portions of the gate structure may form around (e.g., surround) the top semiconductor channel layers 26U and the bottom semiconductor channel layers 26L.

The method 200 proceeds to block 235 where a gate structure including a 2D dielectric material is formed. For example, method 100 of FIG. 2A is implemented at block 235 to form a gate structure for each of the devices 12L, 12U. With reference to FIGS. 4G and 4H, after exposing the semiconductor channel layers 26U, 26L and in an embodiment of block 235, a 2D dielectric material (e.g., 2D silica and/or 2D silicate) 79U is formed over exposed surfaces of the top semiconductor channel layers 26U and a 2D dielectric material (e.g., 2D silica and/or 2D silicate) 79L is formed over exposed surfaces of the bottom semiconductor channel layers 26L. The 2D dielectric materials 79U, 79L may be formed as described above, and in some cases the 2D dielectric materials 79U, 79L may form around (e.g., surround) respective ones of the top semiconductor channel layers 26U and the bottom semiconductor channel layers 26L. In various cases, the 2D dielectric materials 79U, 79L do not form on sidewall surfaces of the gate spacers 44 or on sidewall surfaces of the inner spacers 54, and instead selectively form on exposed surfaces of the semiconductor channel layers 26U, 26L. In some embodiments, each of the 2D dielectric materials 79U, 79L may be the same. In other cases, each of the 2D dielectric materials 79U, 79L may be different. If the 2D dielectric materials 79U, 79L include 2D silica (c-SiOx), a dipole formation step (e.g., deposition of a dipole-inducing layer over the 2D dielectric material and a thermal diffusion process) may be performed to form a silicate and to form a dipole substantially within the silicate. If the 2D dielectric materials 79U, 79L include a 2D silicate (c-MsiOx), a dipole may be formed within the silicate during deposition of the 2D silicate and a separate dipole formation step may be omitted. In some embodiments, an optional buffer layer (e.g., such as the buffer layer 165) may be formed over the semiconductor channel layers 26U, 26L prior to formation of the 2D dielectric materials 79U, 79L. As previously described, the dipole formed within the 2D dielectric materials 79U, 79L may be used to provide WF and Vt tuning of the devices 12L, 12U.

In a further embodiment of block 235, after forming the 2D dielectric materials 79U, 79L and still with reference to FIGS. 4G and 4H, a high-K dielectric layer is formed over the 2D dielectric materials 79U, 79L, and a metal gate electrode is formed over the high-K dielectric layer, as described above, to complete formation of the gates 90 that fill the gate openings 337 and the gaps 339. In some embodiments, a planarization process may be performed to remove portions of the gate dielectric layers and/or portions of the gate electrode layers over the dielectric layer. Each gate 90 includes a respective gate 90L (e.g., a respective gate dielectric 78L, that includes a respective 2D dielectric material 79L, and a respective gate electrode 80L) and a respective gate 90U (e.g., a respective gate dielectric 78U, that includes a respective 2D dielectric material 79U, and a respective gate electrode 80U). Gate 90L is separated from gate 90U by middle, dummy semiconductor layers 26M and isolation structure 17A. In some embodiments, gate 90L is separated from gate 90U by isolation structure 17A only. In the depicted embodiment, each channel region has two upper semiconductor layers 26U, which may be referred to as channel layers 26U, and two lower semiconductor layers 26L, which may be referred to as channel layers 26L. Channel layers 26U are vertically stacked along the z-direction and provide two channels for transistor 20U through which current may flow between epitaxial source/drains 62U. Channel layers 26L are vertically stacked along the z-direction and provide two channels for transistor 20L through which current may flow between epitaxial source/drains 62L. It will be understood that in other embodiments, each channel region of the channel layers 26U, 26L may have a different number of channel layers (e.g., such as one, three, four, or five upper semiconductor layers 26U and one, three, four, or five lower semiconductor layers 26L).

In some embodiments, gates 90U are recessed and/or etched back, such that top surfaces of gates 90U are lower than top surface of ILD layer 72U, and hard masks 92 (which may be referred to as self-aligned contact (SAC) features/structures) are formed over gates 90U. Hard masks 92 include a material that is different than ILD layer 72U and/or subsequently formed ILD layers to achieve etch selectivity during subsequent etching processes. In some embodiments, hard masks 92 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or a combination thereof. In some embodiments, hard masks 92 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or a combination thereof. In some embodiments, hard masks 92 include an amorphous semiconductor material, such as amorphous silicon. In some embodiments, hard masks 92 are formed by depositing a hard mask material that fills recesses formed over gates 90U (e.g., recesses having sidewalls formed by gate spacers 44 and bottoms formed by recessed gates 90U) and planarizing the hard mask material.

The method 200 proceeds to block 240 where further processing is performed. For example, in some embodiments, fabricating stacked device structure 10A may further include forming interconnects, such as gate contacts and/or source/drain contacts. For example, upper source/drain contacts may be formed in the dielectric layer (e.g., ILD layer 72U and/or CESL 70U) on epitaxial source/drains 62U and lower source/drain contacts may be formed on epitaxial source/drains 62L. In some embodiments, a source/drain via may be formed that electrically connects a respective epitaxial source/drain 62U and a respective epitaxial source/drain 62L. In such embodiments, the source/drain via may be physically and/or electrically connected to an upper source/drain contact formed on the respective epitaxial source/drain 62U and a lower source/drain contact formed on the respective epitaxial source/drain 62L. Forming the source/drain contacts may include forming source/drain contact openings in the dielectric layer (or substrate 14) that expose epitaxial source/drains 62U (or epitaxial source/drains 62L) and forming at least one electrically conductive layer in the source/drain contact openings. In some embodiments, forming the source/drain contact openings includes forming a patterned mask layer (e.g., an etch mask) over the dielectric layer (or substrate) and etching exposed portions of the dielectric layer (or substrate). In some embodiments, forming at least one electrically conductive layer in the source/drain contact openings includes forming metal silicide layers over the epitaxial source/drains, depositing a barrier/liner layer that partially fills the source/drain contact openings, depositing a metal layer over the barrier/liner layer that fills remainders of the source/drain contact openings, and performing a planarization process to remove portions of the barrier/liner layer and/or the metal layer that are disposed over the tops of the dielectric layer and/or the gate structures. A source/drain contact may thus include a metal silicide layer, a barrier/liner layer, and a bulk metal layer, where the barrier/liner layer is between the bulk metal layer and the dielectric layer (or substrate) and the bulk metal layer and the metal silicide layer. In some embodiments, one or more insulation layers may be formed in the source/drain contact openings and processed to form contact spacers, such as dielectric layers and/or air gaps, along sidewalls of electrically conductive portions of the source/drain contacts.

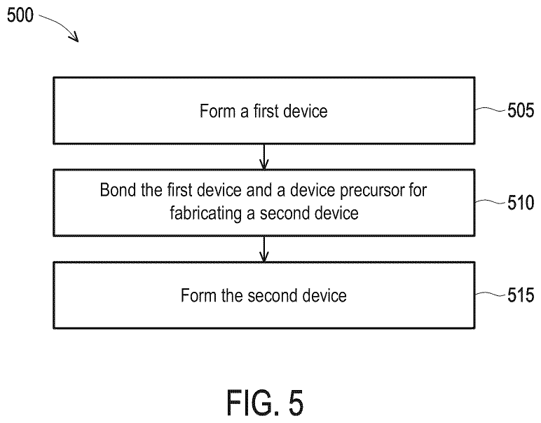

Referring now to FIG. 5, illustrated therein is a flow chart of a method 500 for sequentially fabricating a stacked device structure, such as stacked device structure 10B of FIG. 1B, that implements the methods of forming a gate structure of FIGS. 2A-2F, according to various aspects of the present disclosure. The method 500 of FIG. 5 has been simplified for the sake of clarity to better understand the inventive concepts of the present disclosure. Additional steps may be provided before, during, and after method 500, and some of the steps described may be moved, replaced, or eliminated for additional embodiments of method 500.

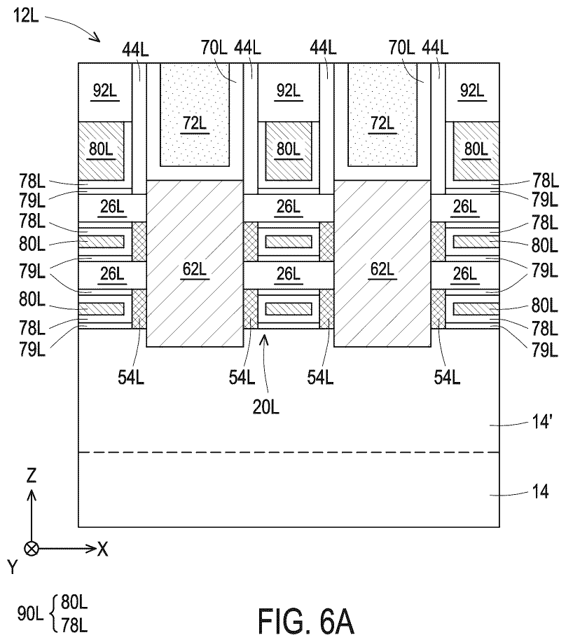

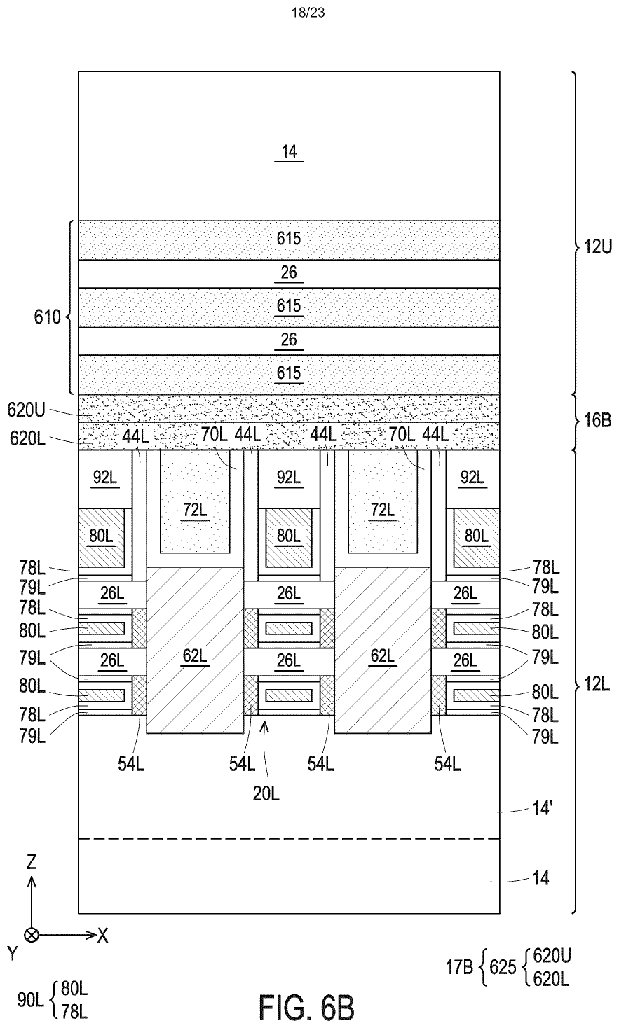

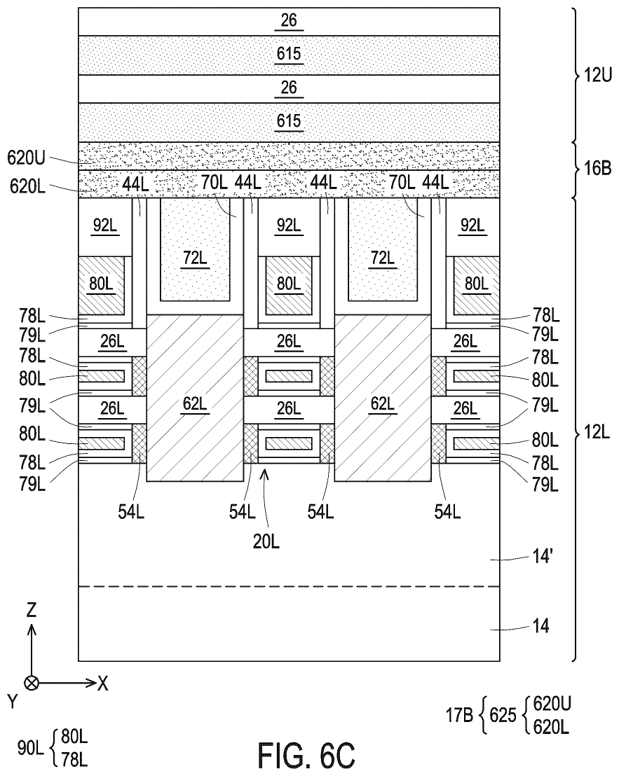

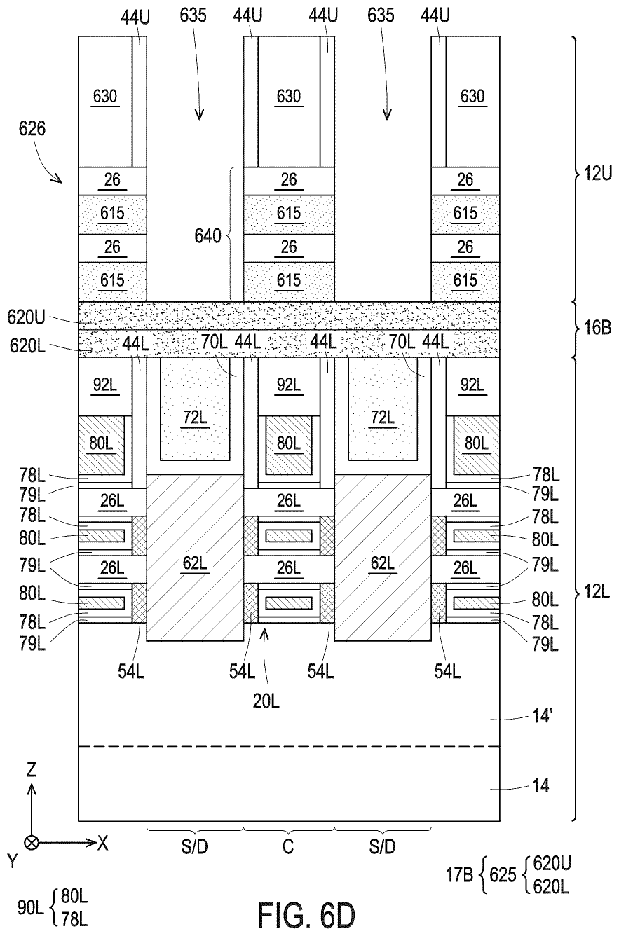

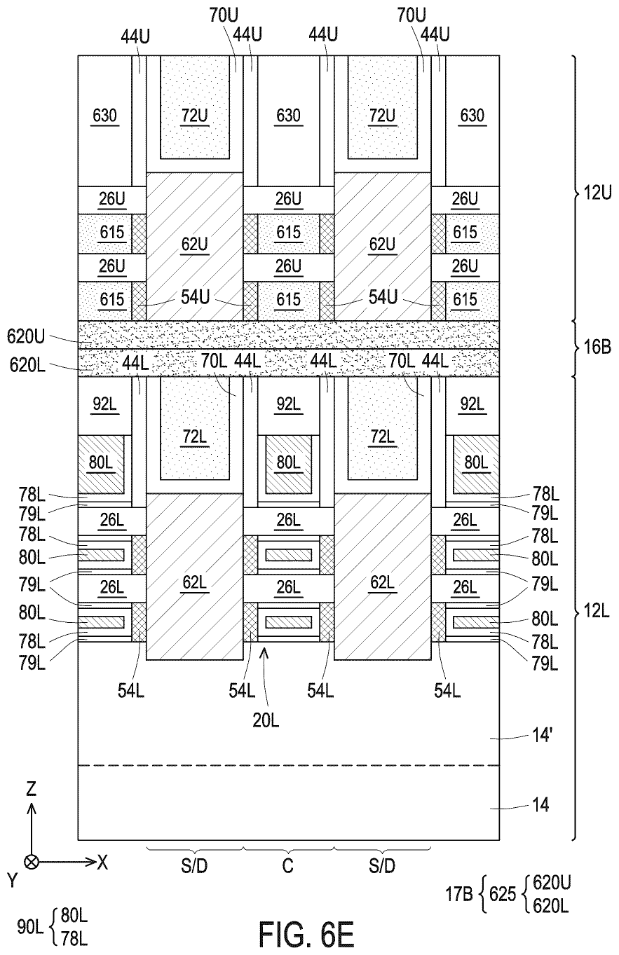

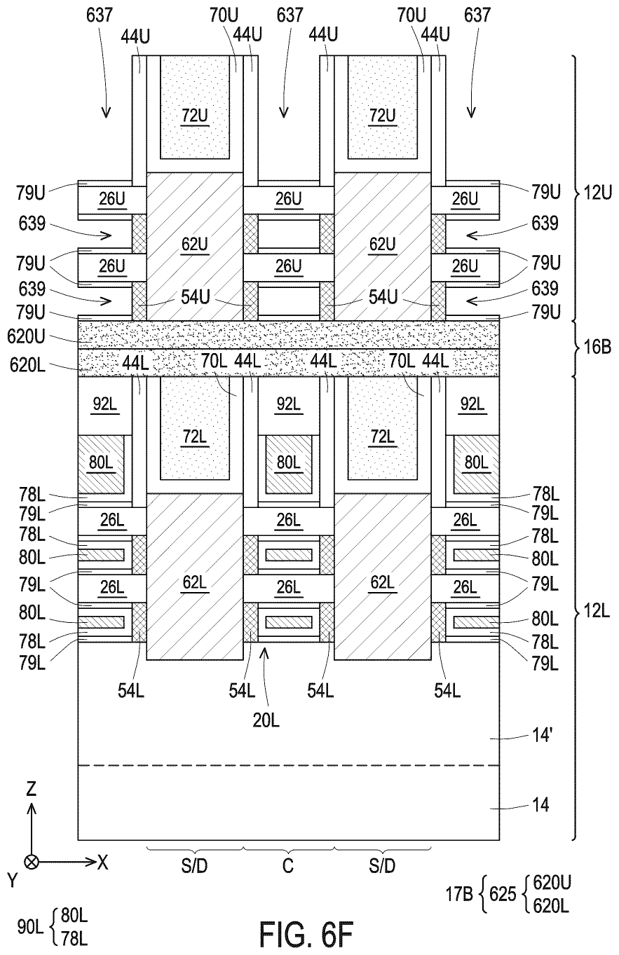

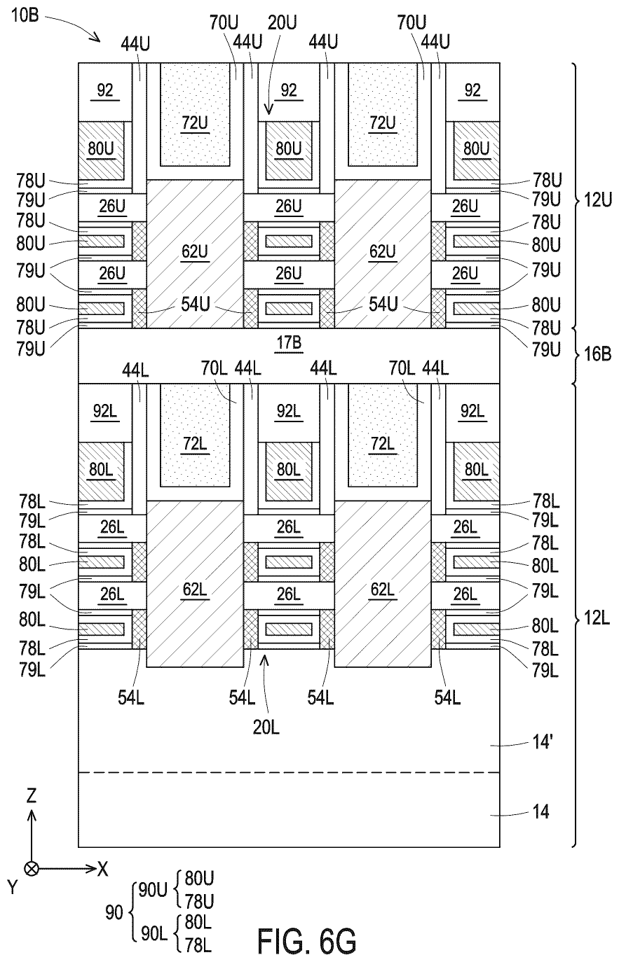

FIGS. 6A-6G are cross-sectional views of stacked device structure 10B, in portion or entirety, at various sequential fabrication stages, such as those associated with method 500 of FIG. 5 when implementing the methods of forming a gate structure of FIGS. 2A-2F, according to various aspects of the present disclosure. FIGS. 6A-6G have been simplified for the sake of clarity to better understand the inventive concepts of the present disclosure. Additional steps may be provided before, during, and after the sequential fabrication steps of FIGS. 6A-6G, and some of the steps described may be moved, replaced, or eliminated for additional embodiments of the sequential fabrication steps of FIGS. 6A-6G. Additional features may be added in stacked device structure 10B of FIGS. 6A-6G, and some of the features described below may be replaced, modified, or eliminated in other embodiments of stacked device structure 10B of FIGS. 6A-6G.

Referring to FIG. 6A, and in an embodiment of block 505, fabricating stacked device structure 10B includes forming a first device, which may include the device 12L described above. Thus, in some examples, forming the first device of block 505 may be substantially the same as forming the device 12L of the stacked device structure 10A, as previously discussed. Forming device 12L may include forming a semiconductor layer stack over a respective substrate 14 and patterning the semiconductor layer stack (and, in some embodiments, substrate 14) to form a fin extending from substrate 14. The semiconductor layer stack may be similar to semiconductor layer stack 310L. For example, the semiconductor layer stack may include first semiconductor layers (e.g., semiconductor layers 26) and second semiconductor layers stacked vertically (e.g., along the z-direction) in an interleaving and/or alternating configuration from a top surface of substrate 14. The second semiconductor layers (e.g., silicon germanium layers) may be similar to semiconductor layers 315 described above. The fin may be similar to fin 326. For example, the fin may include a patterned portion of semiconductor layer stack and a patterned portion of substrate 14 (i.e., mesa 14′), such as described above with reference to FIG. 4C (e.g., semiconductor layer stack 310L over mesa 14′, respectively). In some embodiments, forming device 12L may include forming substrate isolation structures, such as substate isolation structures 328, adjacent to and/or surrounding a lower portion of the fin, such as described above with reference to FIG. 4D.

Forming device 12L may further include forming dummy gate structures over channel regions of the fin, forming source/drain recesses in source/drain regions of the fin, and forming inner spacers 54L. In some embodiments, forming the dummy gate structures includes forming at least one dummy gate layer (e.g., a dummy gate dielectric, a dummy gate electrode, and a hard mask layer) over the fin, patterning the at least one dummy gate layer to form dummy gate stacks, and forming gate spacers 44L along sidewalls of the dummy gate stacks. The dummy gate stacks and gate spacers 44L may be similar to dummy gate stacks 330 and gate spacers 44, respectively, described above with reference to FIG. 4E. In some embodiments, forming the source/drain recesses may include performing an etching process that selectively removes the first semiconductor layers and the semiconductor layers relative to the gate structures. Remainders of the first semiconductor layers (e.g., semiconductor layers 26) of the fin form channel layers 26L in the channel regions, such as described below and above with reference to FIG. 4F. In some embodiments, forming inner spacers 54L includes laterally etching the second semiconductor layers to form gaps between the first semiconductor layers and between the first semiconductor layers and mesas 14′ and at least partially filling the gaps with a dielectric material (e.g., deposit and etch a dielectric layer(s)), such as described above with reference to FIG. 4F.

Forming device 12L may further include forming epitaxial source/drains 62L in the source/drain recesses and forming a dielectric layer (e.g., CESL 70L and ILD layer 72L) over epitaxial source/drains 62L, such as described above with reference to FIG. 4F. Forming device 12L may further include removing the dummy gate stacks (to form gate openings) and performing a channel release process (to form gaps/openings between semiconductor channel layers and between semiconductor channel layers and mesas 14′), such as described above with reference to FIG. 4G. Forming device 12L may further include forming a gate structure including a 2D dielectric material. For example, after forming the gate openings and performing the channel release process, a 2D dielectric material (e.g., 2D silica and/or 2D silicate) 79L is formed over exposed surfaces of the semiconductor channel layers 26L, such as described above with reference to FIG. 4G. Forming device 12L may further include forming a high-K dielectric layer over the 2D dielectric material 79L and forming a metal gate electrode over the high-K dielectric layer to complete formation of gates 90L that fills the gate openings and the gaps formed by the channel release process, such as described above with reference to FIG. 4H. In some embodiments, a planarization process is also performed to remove portions of the gate dielectric layers and/or portions of the gate electrode layers disposed over the dielectric layer. The gate dielectric layers and/or the gate electrode layers fill the gaps, such that the gate dielectric layers and/or the gate electrode layers may form around (e.g., surround) semiconductor channel layers 26L. In some embodiments, forming device 12L may further include forming hard masks 92L (e.g., SAC structures) over gates 90L, such as described above with reference to FIG. 4H.

In some embodiments, fabrication of device 12L may further include forming interconnects, such as gate contacts and/or source/drain contacts, of device 12L. For example, source/drain contacts may be formed in the dielectric layer (e.g., ILD layer 72L and/or CESL 70L) on epitaxial source/drains 62L. Forming the source/drain contacts may include forming source/drain contact openings in the dielectric layer that expose epitaxial source/drains 62L and forming at least one electrically conductive layer (e.g., metal) in the source/drain contact openings. In some embodiments, forming the source/drain contact openings includes forming a patterned mask layer (e.g., an etch mask) over the dielectric layer and etching exposed portions of the dielectric layer. In some embodiments, forming at least one electrically conductive layer in the source/drain contact openings includes forming metal silicide layers over epitaxial source/drains 62L, depositing a barrier/liner layer that partially fills the source/drain contact openings, depositing a metal layer over the barrier/liner layer that fills remainders of the source/drain contact openings, and performing a planarization process to remove portions of the barrier/liner layer and/or the metal layer that are disposed over the tops of the dielectric layer and/or the gate structures. A source/drain contact may thus include a metal silicide layer, a barrier/liner layer, and a bulk metal layer, where the barrier/liner layer is between the bulk metal layer and the dielectric layer (e.g., CESL 70L) and the bulk metal layer and the metal silicide layer. In some embodiments, one or more insulation layers may be formed in the source/drain contact openings and processed to form contact spacers, such as dielectric layers and/or air gaps, along sidewalls of electrically conductive portions of the source/drain contacts.

After fabricating the device 12L, the method 500 proceeds to block 510, where the first device is bonded to a device precursor for fabricating a second device. Referring to FIG. 6B, in an embodiment of block 510, device 12L is bonded to a device precursor for fabricating a second device (device 12U). The device precursor for device 12U includes a semiconductor layer stack 610 disposed over a respective substrate 14. Semiconductor layer stack 610 includes semiconductor layers 26 and semiconductor layers 615 stacked vertically (e.g., along the z-direction) in an interleaving and/or alternating configuration from a top surface of substrate 14. Semiconductor layers 615 (e.g., silicon germanium layers) may be similar to semiconductor layers 315 described above.

As shown in FIG. 6B, the device precursor of device 12U (e.g., a backside thereof) is attached and/or bonded to device 12L (e.g., a frontside thereof). The attaching/bonding may include flipping over the device precursor of device 12U, aligning the device precursor of device 12U with device 12L, contacting the device precursor of device 12U to device 12L, and performing an annealing process, thereby providing a stacked device structure. For example, a bonding dielectric layer 620U of the device precursor of device 12U is brought into contact with a bonding dielectric layer 620L of device 12L (or vice versa) under a temperature, a pressure, an atmosphere, or a combination thereof for a time that effectuates bonding of the bonding dielectric layer 620U and the bonding dielectric layer 620L. In some embodiments, one or both of the bonding dielectric layer 620U and the bonding dielectric layer 620L may include a plasma activated bonding dielectric layer. After bonding, device 12L is attached to and electrically isolated from the device precursor of device 12U by an insulation/bonding layer 625, which includes the bonding dielectric layer 620U and the bonding dielectric layer 620L. Accordingly, at this stage of processing, insulation/bonding layer 625 provides isolation structure 16B of stacked device structure 10B, which electrically isolates and separates device 12L and device 12U. In some embodiments, a thickness of insulation/bonding layer 625 is about 10 nm-100 microns. In some examples, a thickness of insulation/bonding layer 625 is about 1-100 nm. In some cases, the thickness of insulation/bonding layer 625 is about 10-50 nm. Referring to FIG. 6C, and in furtherance of the embodiment of block 510, fabricating stacked device structure 10B includes performing a thinning process to remove substrate 14 and top semiconductor layer 615 from the device precursor of device 12U.

After the first device is bonded to a device precursor for fabricating a second device, the method 500 proceeds to block 515, where fabricating stacked device structure 10B includes forming a second device, which may include the device 12U described above. Thus, in some examples, forming the second device of block 515 may be substantially the same as forming the device 12U of the stacked device structure 10A, as previously discussed.

Referring to FIGS. 6C and 6D, forming device 12U may include patterning semiconductor layer stack 610 to form fins 626 extending from isolation structure 16B, forming dummy gate stacks 630 over portions of fins 626, forming gate spacers 44U along sidewalls of dummy gate stacks 630, and forming source/drain recesses 635. Dummy gate stacks 630 extend lengthwise in a direction that is different than (e.g., orthogonal to) the lengthwise direction of fins 626. For example, dummy gate stacks 630 extend along the y-direction, having a length in the y-direction, a width in the x-direction, and a height in the z-direction. In the X-Z plane, dummy gate stacks 630 are disposed over tops of channel regions (C) of fins 626 and/or stacked device structure 10B, and dummy gate stacks 630 are disposed between source/drain regions (S/D) of fins 626 and/or stacked device structure 10B. In the Y-Z plane, dummy gate stacks 630 may be disposed on tops and sidewalls of fins 626, and dummy gate stacks 630 may wrap channel regions. Dummy gate stacks 630 may be similar to dummy gate stacks 330, such as described above with reference to FIG. 4E. For example, dummy gate stacks 630 may include a dummy gate dielectric, a dummy gate electrode, a hard mask, other suitable layers, or a combination thereof.

Source/drain recesses 635 may be formed by performing an etching process that removes semiconductor layer stack 610 in source/drain regions of fins 626, thereby exposing insulation/bonding layer 625 (e.g., bonding dielectric layer 620U thereof). Each source/drain recess 635 has respective sidewalls formed by respective remaining portions of semiconductor layer stack 610 in channel regions of fins 626 and a bottom formed by bonding dielectric layer 625. In the depicted embodiment, after forming source/drain recesses 635, each channel region has a channel portion 640 formed by a remainder of semiconductor layer stack 610. Channel portion 640 is separated from a channel portion/gate portion of device 12L by bonding/isolation layer 625. The etching process is a dry etch, a wet etch, other suitable etch, or a combination thereof. In some embodiments, the etching process is a multistep etch process.

Referring to FIGS. 6D and 6E, forming device 12U may further include forming inner spacers 54U under gate spacers 44U along sidewalls of semiconductor layers 615, such as described above with reference to FIG. 4F; forming epitaxial source/drains 62U in source/drain recesses 635, such as described above with reference to FIG. 4F; and forming a dielectric layer (e.g., CESL 70U and ILD layer 72U) over epitaxial source/drains 62U, such as described above with reference to FIG. 4F. Epitaxial source/drains 62U are disposed vertically over epitaxial source/drains 62L, and epitaxial source/drains 62U may be electrically isolated from epitaxial source/drains 62L and/or source/drain contacts thereto (such as source/drain contacts disposed in ILD layer 72L and/or CESL 70L, which may extend from bonding/isolation layer 625 to epitaxial source/drains 62L) by bonding/insulation layer 625. Semiconductor layers 26 extending between epitaxial source/drains 62U may be referred to as upper semiconductor layers 26U. The dielectric layer may be formed by depositing CESL 70U over epitaxial source/drains 62U, depositing ILD layer 72L over CESL 70L, and performing a planarization process, which may stop upon reaching the gate structures (e.g., dummy gate stacks 630).

Referring to FIGS. 6E and 6F, forming device 12U may further include removing dummy gate stacks 630 to form gate openings 637, after which a channel release process is performed to selectively remove semiconductor layers 615 to form gaps/openings 639 between semiconductor layers 26U and between semiconductor layers 26U and bonding/insulation layer 625 (e.g., by a selective etching process), such as described above with reference to FIG. 4G. As a result of forming the gaps/openings 639, the semiconductor channel layers 26U of device 12U are exposed and ready for subsequent formation of a gate structure thereupon, where the gate structure includes a 2D dielectric material, in accordance with the embodiment disclosed herein. In particular, and in some embodiments, the subsequently formed gate structure, or portions thereof, may fill the gaps/openings 639, such that portions of the gate structure may form around (e.g., surround) the semiconductor channel layers 26U of device 12U.

Still referring to FIGS. 6E and 6F, forming device 12U may further include forming a gate structure including a 2D dielectric material. By way of example, method 100 of FIG. 2A is implemented to form the gate structure for the device 12U. After exposing the semiconductor channel layers 26U, a 2D dielectric material (e.g., 2D silica and/or 2D silicate) 79U is formed over exposed surfaces of the semiconductor channel layers 26U. The 2D dielectric material 79U may be formed as described above, and in some cases the 2D dielectric material 79U may form around (e.g., surround) the semiconductor channel layers 26U. In various cases, the 2D dielectric materials 79U do not form on sidewall surfaces of the gate spacers 44U or on sidewall surfaces of the inner spacers 54U, and instead selectively form on exposed surfaces of the semiconductor channel layers 26U. In some embodiments, the 2D dielectric material 79U may be the same as that used in the gate dielectric of device 12L. In other cases, the 2D dielectric material 79U may be different than that used in the gate dielectric of device 12L. If the 2D dielectric material 79U includes 2D silica (c-SiOx), a dipole formation step (e.g., deposition of a dipole-inducing layer over the 2D dielectric material and a thermal diffusion process) may be performed to form a silicate and to form a dipole substantially within the silicate. If the 2D dielectric material 79U includes a 2D silicate (c-MsiOx), a dipole may be formed within the silicate during deposition of the 2D silicate and a separate dipole formation step may be omitted. In some embodiments, an optional buffer layer (e.g., such as the buffer layer 165) may be formed over the semiconductor channel layers 26U prior to formation of the 2D dielectric material 79U. As previously described, the dipole formed within the 2D dielectric material 79U (and within the 2D dielectric material 79L of device 12L) may be used to provide WF and Vt tuning of the devices.

Referring to FIGS. 6F and 6G, forming device 12U may further include forming a high-K dielectric layer over the 2D dielectric material 79U, and forming a metal gate electrode over the high-K dielectric layer, as described above, to complete formation of the gate 90U that fills the gate openings 637 and the gaps 639. In some embodiments, a planarization process may be performed to remove portions of the gate dielectric layers and/or portions of the gate electrode layers over the dielectric layer. Gate 90U includes a respective gate dielectric 78U, that includes a respective 2D dielectric material 79U, and a respective gate electrode 80U. Gate 90U is separated from gate 90L by isolation structure 17B.

In some embodiments, forming device 12U may further include forming hard masks 92U (e.g., SAC structures) over gates 90U, such as described above with reference to FIG. 4H. In some embodiments, fabricating stacked device structure 10B may further include forming interconnects, such as gate contacts and/or source/drain contacts, of device 12U. For example, source/drain contacts may be formed in the dielectric layer (e.g., ILD layer 72U and/or CESL 70U) on epitaxial source/drains 62U, such as described above with reference to FIG. 6A. In some embodiments, a source/drain via may be formed that electrically connects a respective epitaxial source/drain 62U and a respective epitaxial source/drain 62L. In such embodiments, the source/drain via may be physically and/or electrically connected to a first source/drain contact formed on the respective epitaxial source/drain 62U and a second source/drain contact formed on the respective epitaxial source/drain 62L.

In the depicted embodiment, isolation structure 16B is provided by isolation structure 17B, which separates and/or electrically isolates both channel regions and source/drain regions of device 12U and device 12L. For example, each channel region has two upper semiconductor layers 26U (upper channel layers) and two lower semiconductor layers 26L (lower channel layers) surrounded and/or wrapped by gate 90U and gate 90L, respectively, and gate 90U is separated and/or electrically isolated from gate 90L by isolation structure 17B. Semiconductor layers 26U are vertically stacked along the z-direction and provide two channels for transistor 20U through which current may flow between epitaxial source/drains 62U, and semiconductor layers 26L are vertically stacked along the z-direction and provide two channels for transistor 20L through which current may flow between epitaxial source/drains 62L. Further, epitaxial source/drains 62U may be separated and/or electrically isolated from epitaxial source/drains 62L and/or source/drain contacts thereto (such as source/drain contacts disposed in ILD layer 72L and/or CESL 70L, which may extend from bonding/isolation layer 625 to epitaxial source/drains 62L) by isolation structure 17B, where the isolation structure 17B is formed by the insulation/bonding layer 625. It will be understood that in other embodiments, each channel region of the channel layers 26U, 26L may have a different number of channel layers (e.g., such as one, three, four, or five upper semiconductor layers 26U and one, three, four, or five lower semiconductor layers 26L).

Devices and/or structures described herein, such as stacked device structure 10A, stacked device structure 10B, device 12L, device 12U, transistor 20L, transistor 20U, etc. may be included in a microprocessor, a memory, other IC device, or a combination thereof. In some embodiments, devices and/or structures described herein, such as stacked device structure 10A, stacked device structure 10B, device 12L, device 12U, transistor 20L, transistor 20U, etc. described herein are a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other devices, or a combination thereof.

The various embodiments described herein offer several advantages over the existing art. It will be understood that not all advantages have been necessarily discussed herein, no particular advantage is required for all embodiments, and other embodiments may offer different advantages. As one example, embodiments discussed herein include gate dielectric materials and related methods for stacked device structures, such as stacked transistor structures. In some embodiments, a 2D dielectric material is disposed between the semiconductor channel layer and the high-K dielectric layer of a gate structure. In various examples, the 2D dielectric material may include 2D silica and/or 2D silicate (e.g., such as c-SiOx, c-MSiOx, where ‘M’ is a metal). In particular, the 2D dielectric material disclosed herein provides for both Vt tuning and EOT scaling, without compromising device performance. For instance, an interface between the 2D dielectric material and the underlying semiconductor channel layer (e.g., such as Si) is substantially flat, promoting improved device performance. The crystalline structure of the 2D dielectric material, for example as opposed to the amorphous SiOx used in some existing implementations, also provides for enhanced device reliability. In various embodiments, the ultrathin thickness of the 2D dielectric material provides for a scalable EOT, further enhancing device performance. In addition, and in some embodiments, the 2D dielectric material may be directly doped during the deposition process, thereby providing for the formation of a dipole (e.g., for WF and Vt tuning) in a controllable manner. Additional benefits and/or other advantages will become apparent to those skilled in the art having benefit of the present disclosure.

Thus, one of the embodiments of the present disclosure described a method including forming a two-dimensional (2D) dielectric material over a semiconductor channel layer. In some embodiments, the method further includes depositing a gate dielectric layer over the 2D dielectric material. In some examples, the method further includes forming a metal gate electrode over the gate dielectric layer. In various embodiments, a dipole is formed substantially within the 2D dielectric material, where the dipole is configured to modulate a threshold voltage (Vt) of the semiconductor device.

In another of the embodiments, discussed is a method including forming a stacked device structure having a first device vertically stacked over a second device. In some embodiments, the first and second devices have respective first and second gate stacks. In some examples, forming at least one of the first and second gate stacks includes performing a channel release process to selectively remove a dummy layer from between adjacent channel layers and form a gap between the adjacent channel layers that exposes opposing surfaces of the adjacent channel layers. In some embodiments, the forming the at least one of the first and second gate stacks further includes forming a two-dimensional (2D) dielectric material over the exposed opposing surfaces of the adjacent channel layers, where the 2D dielectric material includes a dipole-inducing element that provides a dipole within the 2D dielectric material. In some examples, the forming the at least one of the first and second gate stacks further includes depositing a high-K gate dielectric over the 2D dielectric material.

In yet another of the embodiments, discussed is a semiconductor device including a semiconductor channel layer, a two-dimensional (2D) dielectric material disposed over the semiconductor channel layer, a high-K dielectric layer disposed over the 2D dielectric material, and a metal gate electrode disposed over the high-K dielectric layer. In some embodiments, the 2D dielectric material includes a dipole-inducing element that forms a dipole within the 2D dielectric material for modulating a threshold voltage (Vt) of the semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a plurality of channel layers stacked over a substrate;
forming a two-dimensional (2D) material over at least one of the plurality of channel layers, wherein the 2D material has a hexagonal crystal structure, wherein a dipole profile is defined within the 2D material, and wherein the dipole profile corresponds to a quantity and location of at least one of metal atoms and metal ions within the 2D material;
depositing a high-K dielectric layer over the 2D material; and
forming an electrically conductive material over the high-K dielectric layer.

2. The method of claim 1, wherein the 2D material includes crystalline 2D silica (c-SiOx).

3. The method of claim 1, wherein the 2D material includes crystalline 2D silicate (c-MSiOx), and wherein ‘M’ is a metal.

4. The method of claim 1, wherein the 2D material consists of X-member rings, and wherein ‘X’ is between 3 and 9.

5. The method of claim 1, wherein the 2D material is free of grain boundaries.

6. The method of claim 1, wherein the 2D material has a bilayer structure.

7. The method of claim 1, further comprising:
prior to forming the 2D material, forming a crystalline buffer layer over the at least one of the plurality of channel layers; and
forming the 2D material over the crystalline buffer layer.

8. The method of claim 1, wherein the forming the 2D material further comprises:
depositing the 2D material at room temperature; and
after depositing the 2D material, annealing the 2D material at a temperature greater than room temperature.

9. The method of claim 1, wherein the forming the 2D material further comprises:
forming a dipole-inducing layer over the 2D material; and
after forming the dipole-inducing layer, performing a thermal diffusion process to drive the metal ions from the dipole-inducing layer into the 2D material to form the dipole profile.

10. The method of claim 1, wherein the forming the 2D material further comprises:
during formation of the 2D material, providing a metal source that causes the metal atoms to be incorporated into the 2D material to form the dipole profile.

11. A method, comprising:
forming a transistor stack having a first transistor disposed over a second transistor, wherein the first transistor and the second transistor have opposite conductivity types, and wherein forming at least one of a first gate of the first transistor and a second gate of the second transistor comprises:
removing a dummy layer adjacent to a top surface and a bottom surface of a semiconductor channel layer to expose the top and bottom surfaces of the semiconductor channel layer;
forming a two-dimensional (2D) material that wraps around the semiconductor channel layer including over the exposed top and bottom surfaces of the semiconductor channel layer, wherein the 2D material has a hexagonal crystal structure, and wherein a dipole profile is defined within the 2D material; and
depositing a gate dielectric layer over the 2D material.

12. The method of claim 11, wherein the 2D material includes crystalline 2D silica (c-SiOx).

13. The method of claim 11, wherein the 2D material includes crystalline 2D silicate (c-MSiOx), and wherein ‘M’ is a metal.

14. The method of claim 11, wherein the 2D material has a bilayer structure.

15. The method of claim 11, further comprising:
prior to forming the 2D material, forming a crystalline buffer layer that wraps around the semiconductor channel layer including over the exposed top and bottom surfaces of the semiconductor channel layer; and
forming the 2D material over the crystalline buffer layer.

16. The method of claim 11, wherein the forming the 2D material further comprises:
forming a dipole-inducing layer over the 2D material; and
after forming the dipole-inducing layer, performing a thermal diffusion process to drive metal ions from the dipole-inducing layer into the 2D material to form the dipole profile.

17. The method of claim 11, wherein the forming the 2D material further comprises:
during formation of the 2D material, providing a metal source that causes metal atoms to be incorporated into the 2D material to form the dipole profile.

18. A semiconductor device comprising:
a transistor channel layer;
a two-dimensional (2D) material surrounding the transistor channel layer, wherein the 2D material includes crystalline 2D silica or crystalline 2D silicate, wherein the 2D material has a hexagonal crystal structure, and wherein at least one of metal atoms and metal ions are incorporated within the 2D material to define a dipole profile that corresponds to a quantity and location of the at least one of the metal atoms and the metal ions within the 2D material;
a gate dielectric layer disposed over the 2D material; and
an electrically conductive layer disposed over the gate dielectric layer.

19. The semiconductor device of claim 18, wherein the dipole profile is shifted towards the gate dielectric layer and nearer to a top side of the 2D material.

20. The semiconductor device of claim 18, wherein the dipole profile is shifted towards the transistor channel layer and nearer to a bottom side of the 2D material.
